(19) United States
(12) Patent Application Publication
(10) Pub. No.: US 2004/0241923 A1
(43) Pub. Date: Dec. 2, 2004

(54) Laser annealing apparatus and laser annealing method

(75) Inventor: Masahiro Toida, Kanagawa (JP)

Correspondence Address: SUGHRUE MION, PLLC, 2100 PENNSYLVANIA AVENUE, N.W., SUITE 800, WASHINGTON, DC, 20037, US

(73) Assignee: FUJI PHOTO FILM CO., LTD.

(21) Appl. No.: 10/853,116

(22) Filed: May 26, 2004

(30) Foreign Application Priority Data
May 26, 2003 (JP) 2003-148027

(51) Int. Cl. H01L 21/00; H01L 21/324; H01L 21/477

(52) U.S. Cl. 438/166; 438/795

(57) ABSTRACT

A temperature distribution which is of the sum of the temperature distribution generated by a laser beam emitted from above and the temperature distribution generated by the laser beam emitted from below at the same irradiation position in a film which is of a subject of laser annealing is caused to be substantially constant in a thickness direction of the subject to be annealed. Therefore, a solid-liquid interface is formed substantially perpendicular to a surface direction of the subject to be annealed, crystal growth in a lateral direction is promoted, and a large crystal grain can be formed. As a result, even if the subject to be annealed has a thin film thickness, the annealing process can be performed by utilizing input energy without waste of the input energy.

### CROSS-REFERENCE TO RELATED APPLICATION

This application claims priority under 35 USC 119 from Japanese Patent Application No. 2003-148027, the disclosure of which is incorporated by reference herein.

### BACKGROUND OF THE INVENTION

1. Field of the Invention

The present invention relates to a laser annealing apparatus which performs an annealing process by irradiating the same position of a film, which is a subject to be irradiated, with laser beams from both a surface side and a backside of the film to simultaneously heat the film from both sides.

2. Description of the Related Art

From a viewpoint of reduction in size and weight, and cost saving of flat-panel displays such as a liquid crystal display (LCD) and an organic electro-luminescence display, both a thin film transistor (TFT) for a pixel display gate and a System On Glass (SOG)-TFT in which a driving circuit; a signal processing circuit, and an image processing circuit are directly formed on a glass substrate of LCD receive attention.

Although amorphous silicon (a-Si) is used for TFT for a pixel display gate, polysilicon (poly-Si) having a large carrier mobility is required for SOG-TFT. However, since the deformation temperature of the glass is as low as 600° C., in formation of a poly-Si film, it is impossible to use a crystal growth technology utilizing a high temperature of more than 600° C. Therefore, excimer laser annealing (ELA) in which, after an a-Si film is formed at a lower temperature (100° C. to 300° C.), pulse irradiation of a XeCl excimer laser having a wavelength of 308 nm is performed to thermally fuse the a-Si film, and the a-Si film is crystallized in a cooling process to form the poly-Si film. The poly-Si film can be formed without thermally damaging the glass substrate by the use of ELA.

The conventional laser annealing process in which a-Si is changed into poly-Si is performed by irradiating the a-Si film only from one side with the XeCl excimer laser having a wavelength of 308 nm. Since an absorption coefficient of the XeCl excimer laser having a wavelength of 308 nm to the a-Si film is as large as 1×10⁶ cm⁻¹, input energy is absorbed in a range which is extremely close to a surface (depth from the surface is not more than about 1 nm).

Therefore, when an excimer laser is used, a large temperature gradient is generated in a depth direction in the Si layer fused by the absorption of laser energy and heat transfer, and sometimes the Si layer is only partially-fused, as shown in FIG. 34.

In this case, heat is diffused in a substrate direction and solid-state phase transformation into a crystal phase is generated at 800° C. in the remaining a-Si, which has not fused, so that a crystal nucleus is generated in a boundary portion between the fused Si phase and the a-Si phase. The generated crystal nucleus is grown in an upward direction of FIG. 34 along the temperature gradient. The crystal grain generated from the crystal nucleus collides with the other crystal grain generated from an adjacent crystal nucleus, and the crystal growth is stopped at the state in which the crystal grain is small and there are many grain boundaries.

High charge mobility is required for high performance TFTs. Since the grain boundary becomes an obstacle for movement of electrons, in order to increase electric charge mobility, it is necessary to generate a crystal grain having few grain boundaries, that is, a large crystal grain.

Therefore, as shown in FIG. 35, in the excimer laser anneal, when output of the excimer laser is increased and the remaining a-Si phases are formed in the shape of an island, the number of crystal nucleuses generated is decreased and each crystal grain is grown to a large size.

As shown in FIG. 36, in the excimer laser anneal, when the output of the excimer laser is increased and the a-Si phases are completely fused, the Si layer enters a super cooling state in which crystallization is not started even if the temperature is decreased below the melting point. Then, when the temperature is further decreased, the crystal nucleuses are simultaneously generated to fill the Si layer with minute crystal grains.

FIG. 37 quantitatively shows a relationship between the laser intensity and the diameter of the crystal grain. As the laser intensity is increased, the diameter of the crystal grain is increased such that the Si layer changes from a partially fused state (a) to a fused state (b) in which the remaining a-Si phases are formed in an island shape. Once the laser intensity exceeds the intensity in which a-Si is completely fused, the Si layer becomes a perfectly fused state (c), and the diameter of the crystal grain is remarkably decreased. Output stability of the excimer laser is not good, and usually a fluctuation in intensity ranging from 10 to 15% can not be avoided (shown by the hatched area in FIG. 37). Therefore, the diameter of the crystal grain obtained by the excimer laser annealing is currently about 0.3 μm at most. This is also the limitation caused by setting a crystal growth direction to a vertical direction.

Thus, there has been devised an annealing method which controls the crystal growth in lateral direction in such a manner that the laser beam is slowly scanned on a substrate so as not to completely fuse a-Si to not generate the super cooling state.

In the annealing method, as shown in FIG. 38, although the crystal nucleus is generated from the a-Si layer which is not irradiated with the laser beam, the crystal growth proceeds from the crystal nucleus in a bottom portion of the boundary between a-Si and the fused layer in an obliquely upward direction due to the temperature gradient. Since the temperature gradient is present in the depth direction, it is thought that a solid-liquid interface is inclined and the crystal growth proceeds perpendicular to the oblique solid-liquid interface.

The size of the crystal grain is restricted by a film thickness and the collision with other crystal grains from the opposite side. The essential cause is the large temperature gradient in the depth direction of the fused layer.

In order to solve the problem of the crystal growth in the lateral direction in the excimer laser, there has been devised laser annealing which uses a light beam having a wavelength of 532 nm of a high-output Nd:YVO₄ laser in which the laser output stability is high (1%).

Since the absorption coefficient of a light beam having the wavelength of 532 nm of the Nd:YVO₄ laser to the a-Si film is 5×10⁴ cm⁻¹, a film thickness of 460 nm is required to absorb 90% of the input energy. The absorption coefficient of a light beam having a wave length of 532 nm of the Nd:YVO₄ laser is smaller than that of the light beam having a wavelength of 308 nm of the excimer laser by 1.5 digits. As shown in FIG. 39, when the laser beams are compared to each other with the same film thickness, in the light beam having the wavelength of 532 nm, the temperature gradient in the depth direction becomes more flat and the solid-liquid interface is easy to form vertically. Therefore, a growth distance in the lateral direction takes longer and a large crystal grain is generated.

In order to solve the problem of crystal growth in the lateral direction using an excimer laser, there is disclosed a laser annealing method in which a sample having a four-layer structure of a-Si/SiO₂ insulating thin film/Cr light absorber thin film/substrate is irradiated from both sides with the laser beam (308 nm) of an excimer laser. In this method, a heat sink under the SiO₂ layer is generated by absorbing the laser energy from a backside in the Cr light absorber thin film. As a result, the heat of the Si layer generated by the laser energy from the surface side is hardly transferred to the substrate direction. As transfer velocity of thermal energy accumulated in the Si layer is decreased, the heat is transferred in the direction of the Si film surface, and the crystal growth in the lateral direction is controlled (for example, see Surface Chemistry vol. 21, No. 5, pp.278 to 287 (2000)).

Further, there is disclosed a laser annealing apparatus for both-side irradiation by a solid-state laser, in which a second harmonic wave (532 nm), a third harmonic wave (355 nm), and a fourth harmonic wave (266 nm) of a Nd:YAG laser are utilized.

In the both-side irradiation laser annealing apparatus, the individual laser beam passes through the Si layer one time from the surface and the backside. That is to say, the annealing process is performed in such a manner that the same position of a Si film is irradiated with the laser beam from the backside, while the same position of Si film the laser beam is irradiated with the laser beam from the surface side (see Japanese Patent Application Laid-Open(JP-A) No. 2001-144027).

In the laser annealing method, which utilizes the XeCl excimer laser, the output of the light beam is not stable, and output intensity fluctuates in a range within ±10%. In ELA, the diameter sizes of the crystal grains are varied in the poly-Si film and reproducibility is poor. In the XeCl excimer laser, a repeated frequency of pulse drive is as low as 300 Hz. In ELA, therefore, it is difficult to form a continuous crystal grain, high-carrier mobility is not obtained, and a large area of the Si film can not be annealed at high speed. Further, in the XeCl excimer laser, there is the intrinsic problem that maintenance cost is high due to short lives of a laser tube and laser gas (as low as about 1×10⁷ shots), the apparatus is enlarged, and energy efficiency is as low as 3%.

In order to improve the performance of TFT, it is also important to thin the crystal film (not more than 50 nm) in addition to increasing the diameter of the crystal grain.

However, in the laser annealing method which utilizes the light beam having the wavelength of 532 nm of the Nd:YVO₄ laser in which the solid-liquid interface effective to the formation of the large crystal grain can be formed vertically, since the absorption coefficient of the light beam having the wavelength of 532 nm of the Nd:YVO₄ laser to the a-Si film is small, although the solid-liquid interface is formed vertically, a film thickness not lower than 150 nm is required in order to secure the energy absorption necessary to fuse the a-Si film.

Therefore, in the laser annealing method, the vertical formation of the solid liquid interface effective to the formation of a large crystal grain is contradictory to the thinning of the crystal film. Optical properties of a-Si cause the contradiction, and it is difficult to balance these contradictory demands with each other.

Further, since a film thickness of 460 nm is required to absorb 90% of the input energy in the laser annealing method which utilizes a light beam having a wavelength of 532 nm of the Nd:YVO₄ laser, waste of the input energy is remarkably increased when the a-Si film becomes thin, e.g. about 50 nm.

In view of the foregoing, it is an object of the invention to provide the laser annealing apparatus which can form the large crystal grain by uniformly absorbing laser energy without waste of laser energy and can crystallize a thin film.

### SUMMARY OF THE INVENTION

A laser annealing apparatus of a first aspect of the invention comprises: a laser light source, which includes a GaN-based semiconductor laser; a first optical path which irradiates a film-shaped subject to be annealed from a first surface of the subject to be annealed with a first laser beam divided from a laser beam emitted from the laser light source; a second optical path which irradiates an irradiation position of the film-shaped subject to be annealed from the other surface of the film-shaped subject to be annealed with a second laser beam divided from the laser beam emitted from the laser light source, the irradiation position corresponding to a position on the first surface being irradiated by the first laser beam; and a scanning unit, which performs scanning by relatively moving the film-shaped subject to be annealed and the first and second laser beams.

According to the laser annealing apparatus of the first aspect of the invention, when the annealing process is performed by irradiating the subject to be annealed from both the surface side and the backside with the laser beam having the relatively short wavelength emitted from the GaN-based semiconductor laser, since the light energy of the laser beam is inputted into the subject to be annealed to be absorbed in both the surface side and the backside, effective utilization of the inputted light energy can be achieved. Further, a total absorption energy distribution, which is of a sum of the absorption energy distribution in the film in the case where the subject to be annealed is irradiated with the laser beam from one of the surfaces of the subject to be annealed and the absorption energy distribution in the film in the case where the subject to be annealed is irradiated with the laser beam from the other surface of the subject to be annealed, can be uniform in a film thickness direction of the subject to be annealed. Therefore, a large crystal grain can be formed in such a manner that the solid-liquid interface is formed substantially perpendicular to a surface direction of the subject to be annealed and the crystal growth proceeds in a lateral direction.

Stability of the GaN-based semiconductor laser light source is further improved when the GaN-based semiconductor laser light source is driven, output of each GaN-based semiconductor laser device can be relatively strengthened in the semiconductor lasers, adjustments of higher output or relative low output can be easily performed by increasing or decreasing the total number of the GaN-based semiconductor devices, and the GaN-based semiconductor laser light source is inexpensive. As a result, a product of the laser annealing apparatus can be manufactured at lower cost.

A laser annealing apparatus of a second aspect of the invention comprises: a first laser light source and a second light source which emit a first laser beam and a second laser beam respectively, at least one of the first laser light source and the second light source including a GaN-based semiconductor laser; a first optical path which irradiates a film-shaped subject to be annealed from a first surface of the film-shaped subject to be annealed with the first laser beam emitted from the first laser light source; a second optical path which irradiates an irradiation position on the other surface of the film-shaped subject to be annealed with the second laser beam emitted from the second laser light source, the irradiation position corresponding to a position on the first surface being irradiated by the first laser beam; and a scanning unit, which performs scanning by relatively moving the film-shaped subject to be annealed and the first and second laser beams.

According to the laser annealing apparatus of the second aspect of the invention, at least one laser light source is configured to output the laser beam emitted from the GaN-based semiconductor laser. When the annealing process is performed by irradiating the subject to be annealed from both the surface side and the backside with the laser beams emitted from the first laser light source and the second laser light source respectively, since the light energy of the laser beam is inputted into the subject to be annealed to be absorbed in both the surface side and the backside, effective utilization of the inputted light energy can be achieved. Further, a total absorption energy distribution, which is of a sum of the absorption energy distribution in the film in the case where the subject to be annealed is irradiated with the laser beam from one of the surfaces of the subject to be annealed and the absorption energy distribution in the film in the case where the subject to be annealed is irradiated with the laser beam from the other surface of the subject to be annealed, can be made uniform in a film thickness direction of the subject to be annealed. Therefore, the large crystal grain can be formed in such a manner that the solid-liquid interface is formed substantially perpendicular to a surface direction of the subject to be annealed and the crystal growth proceeds in a lateral direction.

The total amount of the light energy absorbed in both the surface side and the backside of the subject to be annealed can be increased by utilizing the two independent laser light source.

Since the GaN-based semiconductor laser light source is used as at least one of laser light sources, the stability of the GaN-based semiconductor laser light source is relatively high when the GaN-based semiconductor laser light source is driven, output of each GaN-based semiconductor laser device can be relatively strengthened in the semiconductor lasers, adjustments of higher output or relative low output can be easily performed by increasing or decreasing the total number of the GaN-based semiconductor devices, and the GaN-based semiconductor laser light source is inexpensive. As a result, a product of the laser annealing apparatus can be manufactured at lower cost.

A third aspect of the invention comprises is a laser annealing apparatus of the second aspect, wherein the first laser beam emitted from the first laser light source has a first wavelength, the second laser beam emitted from the second laser light source has a second wavelength, and the first wavelength of the first laser beam and the second wavelength of the second laser beam are set so that a total absorption energy distribution in the film becomes uniform in a film thickness direction of the subject to be annealed, the total absorption energy distribution being equal to a sum of a first absorption energy distribution in the film in the case where the film-shaped subject to be annealed is irradiated with the first laser beam having the first wavelength emitted from the first laser light source from the first surface of the subject to be annealed and a second absorption energy distribution in the film in the case where the film-shaped subject to be annealed is irradiated with the second laser beam having the second wavelength emitted from the second laser light source from the other surface of the subject to be annealed.

According to the laser annealing apparatus of the third aspect of the invention, in addition to action and advantage of the second aspect of the invention, when the annealing process is performed in such a manner that one of the surfaces of the film-shaped subject to be annealed is irradiated with the laser beam having the first wavelength emitted from the first laser light source and the other surface of the film-shaped subject to be annealed is irradiated with the laser beam having the second wavelength emitted from the second laser light source, the total absorption energy distribution of the laser beam inputted into the subject to be annealed to the film-shaped subject can be further uniformed in the film thickness direction of the subject. Therefore, the large crystal grain can be formed better in such a manner that the solid-liquid interface is formed substantially perpendicular to a surface direction of the subject and the crystal growth proceeds in a lateral direction.

A laser annealing apparatus of a fourth aspect of the invention comprises: a laser light source, which emits a laser beam, the laser light source including a GaN-based semiconductor laser; a first optical path which irradiates a film-shaped subject to be annealed with the laser beam on one surface of the film-shaped subject to be annealed; a second optical path which irradiates the film-shaped subject to be annealed with the laser beam on another surface of the film-shaped subject to be annealed; and a scanning unit, which performs scanning by relatively moving the film-shaped subject to be annealed and the laser beam, wherein the laser light source emits a laser beam having a wavelength satisfying the following condition,

α(λ)d≦4.6

where α(λ) is an absorption coefficient when the laser beam is absorbed in the film-shaped subject to be annealed, and d is a film thickness of the film-shaped subject to be annealed.

According to the laser annealing apparatus of the fourth aspect of the invention, when the annealing process is performed by irradiating the subject to be annealed from both the surface side and the backside with the laser beam having the relatively short wavelength emitted from the GaN-based semiconductor laser, since less than 99% of the light energy of the laser beam inputted into the subject is effectively absorbed in the subject, the effective utilization of the inputted light energy can be achieved. Further, a total absorption energy distribution, which is of a sum of the absorption energy distribution in the film in the case where the subject is irradiated with the laser beam from one of the surfaces of the subject and the absorption energy distribution in the film in the case where the subject is irradiated with the laser beam from the other surface of the subject, can be uniformed in a film thickness direction of the subject. Therefore, the large crystal grain can be formed in such a manner that the solid-liquid interface is formed substantially perpendicular to a surface direction of the subject to be annealed and the crystal growth proceeds in a lateral direction.

A laser annealing apparatus of a fifth aspect of the invention comprises: a laser light source, which emits a laser beam; a first optical path which irradiates a film-shaped subject to be annealed with the laser beam on one surface of the film-shaped subject to be annealed; a second optical path which irradiates the subject to be annealed with the laser beam on another surface of the film-shaped subject to be annealed; and a scanning unit for performing scanning by relatively moving the film-shaped subject to be annealed and the laser beam, wherein a light energy distribution in the laser beam emitted from the laser light source is a distribution having a gradient in which light energy intensity is strong on a front end side in a scanning direction of the subject to be annealed and is gradually decreased toward a back end side in the scanning direction.

According to the laser annealing apparatus of the fifth aspect of the invention, in the case where the light energy distribution of the laser beam emitted from the laser light source is strong on the front end side in the scanning direction (conveying direction) of the subject to be annealed and gradually decreased as the distribution proceeds to the back end side in the scanning direction, silicon oxide in the region fused by the laser beam can be controlled so that the crystal is always grown from the crystal nucleus generated in the solid-liquid interface in such a manner that the temperature gradient is controlled so that the temperature is smoothly decreased from the fusion start position to the position of the solid-liquid interface in the fused-state region ranging from a fusion start position on the front end side in the scanning direction where the subject to be annealed is irradiated with the laser beam to start the fusion to the position of the solid-liquid interface on the back end side in the scanning direction. Accordingly, it is possible to prevent the interruption of the formation of the large crystal grain, which is caused by the crystal growth from the crystal nucleus generated in the region partially cooled between the fusion start position and the position of the solid-liquid interface.

A sixth aspect of the invention is characterized in that the laser light source is configured as a fiber array light source in the laser annealing apparatuses of the first to fifth aspects.

According to the sixth aspect of the invention, in addition to any one of operations and advantages of the first to fifth aspects of the invention, the irradiation per unit area with the laser beam having high luminance and high-speed annealing process (improvement of throughput) can be realized by achieving the high output and the high luminance of the laser light source.

A seventh aspect of the invention is a laser annealing method comprising: dividing a laser beam emitted from a laser light source, which includes a GaN-based semiconductor laser, into two laser beams; irradiating a film-shaped subject to be annealed from a first surface of the subject to be annealed with a first laser beam, which is one of the divided laser beams; irradiating an irradiation position of the film-shaped subject to be annealed from the other surface of the film-shaped subject to be annealed with a second laser beam, which is the other of the divided laser beams, the irradiation position corresponding to a position on the first surface being irradiated by the first laser beam; and scanning by relatively moving the film-shaped subject to be annealed and the first and second laser beams.

A eighth aspect of the invention is a laser annealing method comprising.: irradiating a film-shaped subject to be annealed from a first surface of the film-shaped subject to be annealed with a first laser beam emitted from a first laser light source including a GaN-based semiconductor laser; irradiating an irradiation position on the other surface of the film-shaped subject to be annealed with a second laser beam emitted from a second laser light source, the irradiation position corresponding to a position on the first surface being irradiated by the first laser beam; and scanning by relatively moving the film-shaped subject to be annealed and the first and second laser beams.

A ninth aspect of the invention is a laser annealing method comprising: irradiating a film-shaped subject to be annealed with a laser beam emitted from a laser light source on one surface of the film-shaped subject to be annealed; irradiating the subject to be annealed with the laser beam on another surface of the film-shaped subject to be annealed; and scanning by relatively moving the film-shaped subject to be annealed and the laser beam, wherein a light energy distribution in the laser beam emitted from the laser light source is set to be a distribution having a gradient in which light energy intensity is strong on a front end side in a scanning direction of the subject to be annealed and is gradually decreased toward a back end side in the scanning direction.

### BRIEF DESCRIPTION OF THE DRAWINGS

FIG. 1 is a perspective view showing an appearance of a laser annealing apparatus according to an embodiment of the present invention.

FIG. 2 is a view showing an optical path for annealing process in the laser annealing apparatus according to the embodiment of the invention.

FIG. 3 is a graph showing absorption characteristics of amorphous silicon to wavelengths of each laser in the laser annealing apparatus according to the embodiment of the invention.

FIG. 4 shows each in-depth temperature distribution of an a-Si film when an annealing process is performed by means for irradiating the a-Si film with a laser beam from both a surface side and a backside in the laser annealing apparatus according to the embodiment of the invention.

FIG. 5 shows an example of the states in which a crystal is grown from a solid-liquid interface of the a-Si film when the annealing process is performed by the laser beam irradiating means in the laser annealing apparatus according to the embodiment of the invention.

FIG. 6 show an in-depth temperature distribution of the a-Si film when the a-Si film is irradiated with the laser beam from one of the surface sides of the a-Si film for comparison with an advantage of the case in which the annealing process is performed by the laser annealing apparatus according to the embodiment of the invention.

FIG. 7 shows an example of the states in which the crystal is grown from the solid-liquid interface of the a-Si film when the a-Si film is irradiated with the laser beam from one of the surface sides of the a-Si film comparison with the advantage of the case in which the annealing process is performed by the laser annealing apparatus according to the embodiment of the invention.

FIG. 8 show an example of the states in which a crystal grains have been grown in an oblique direction when the a-Si film is irradiated with the laser beam from one of the surface sides of the a-Si film for comparison with the advantage of the case in which the annealing process is performed by the laser annealing apparatus according to the embodiment of the invention.

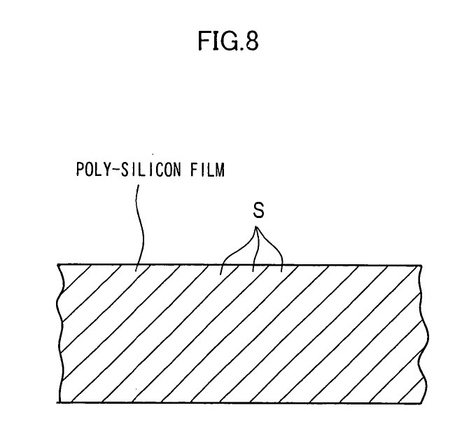

FIG. 9 is a partially expanded view showing a configuration of a digital micromirror device (DMD) in the laser annealing apparatus according to the embodiment of the invention.

FIGS. 10A and 10B are a view for illustrating operation of DMD.

FIG. 11A is a plan view showing arrangement and scanning lines of a scanning beam in the case where DMD is not obliquely arranged, and FIG. 11B is a plan view showing the arrangement and the scanning lines of the scanning beam in the case where DMD is obliquely arranged.

FIG. 12A is a perspective view showing the configuration of a fiber array light source in the laser annealing apparatus according to the embodiment of the invention, and FIG. 12B is a partially expanded view of FIG. 12A.

FIG. 13 shows the configuration of a multi-mode optical fiber.

FIG. 14 is a plan view showing the configuration of a multiplexing laser light source.

FIG. 15 is a plan view showing the configuration of a laser module.

FIG. 16 is a side view showing the configuration of the laser module shown in FIG. 11.

FIG. 17 is a partially side view showing the configuration of the laser module shown in FIG. 12.

FIGS. 18A and 18B show an example of a use area of DMD.

FIG. 19 is a plan view for explaining an annealing method in which a transparent substrate is annealed by a single-time scanning of a scanner.

FIGS. 20A and 20B are a plan view for explaining the annealing method in which the transparent substrate is annealed by plural-time scanning of the scanner.

FIGS. 21A and 21B are a view for illustrating a low-temperature polysilicon TFT forming process.

FIG. 22 shows an optical path for annealing process in which a light beam is modulated into the light beam having desired beam intensity by a spatial light modulator in the laser annealing apparatus according to the embodiment of the invention.

FIG. 23 schematically shows an example of the states of the light beam modulated by the spatial light modulator in the laser annealing apparatus according to the embodiment of the invention.

FIG. 24 shows an example of temperature gradients in a part where a range from a fusion start position to the solid-liquid interface is in a fused state, when the annealing process is performed with the light beam modulated by the spatial light modulator in the laser annealing apparatus according to the embodiment of the invention.

FIG. 25 shows an example of the states of crystal growth in a lateral direction, when the annealing process is performed with the light beam modulated by the spatial light modulator in the laser annealing apparatus according to the embodiment of the invention.

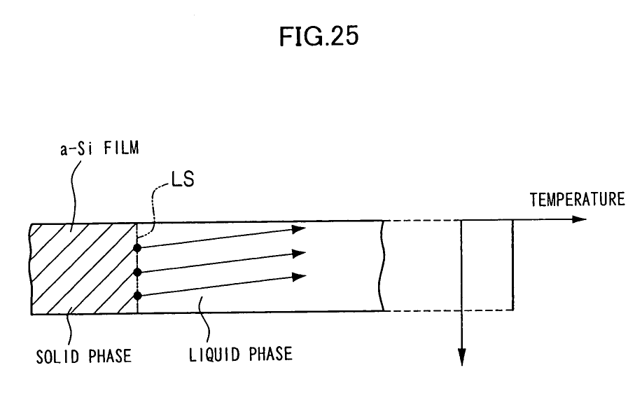

FIG. 26 shows a configuration in which a first optical path and a second optical path are separately formed by using two laser light sources in the laser annealing apparatus according to the embodiment of the invention.

FIG. 27 shows a configuration in which the first optical path and the second optical path are separately formed by using two laser light sources and the two spatial light modulators in the laser annealing apparatus according to the embodiment of the invention.

FIG. 28 shows an optical path for annealing process in which a fiber array light source is used in the laser annealing apparatus according to the embodiment of the invention.

FIG. 29 shows an optical path for annealing process in which the fiber array light source and the spatial light modulator are used in the laser annealing apparatus according to the embodiment of the invention.

FIG. 30 shows a configuration in which the first optical path and the second optical path are separately formed by using the two fiber array light sources in the laser annealing apparatus according to the embodiment of the invention.

FIG. 31 shows a configuration in which the first optical path and the second optical path are separately formed by using two fiber array light sources and the two spatial light modulators in the laser annealing apparatus according to the embodiment of the invention.

FIG. 32 shows an absorption energy distribution of the a-Si film when the a-Si film is irradiated with the laser beam having a wavelength of 460 nm from one of the surface sides of the a-Si film, in order to explain means for performing the annealing process by irradiating the a-Si film with the laser beams having the different wavelengths emitted from the two light sources in the laser annealing apparatus according to the embodiment of the invention.

FIG. 33A shows an absorption energy distribution of each a-Si film when the a-Si film is separately irradiated with the laser beam having the wavelength of 460 nm and laser beam having the wavelength of 400 nm from both the surface side and the backside of the a-Si film in the laser annealing apparatus according to the embodiment of the invention, and FIG. 33B shows an absorption energy distribution of each a-Si film when the annealing process is performed by irradiating the surface side and the backside of the a-Si film with the light beam having the wavelength of 400 nm for comparison with the case of FIG. 33A.

FIG. 34 is an explanatory view showing the state in which a silicon layer is partially melted by the conventional excimer laser annealing.

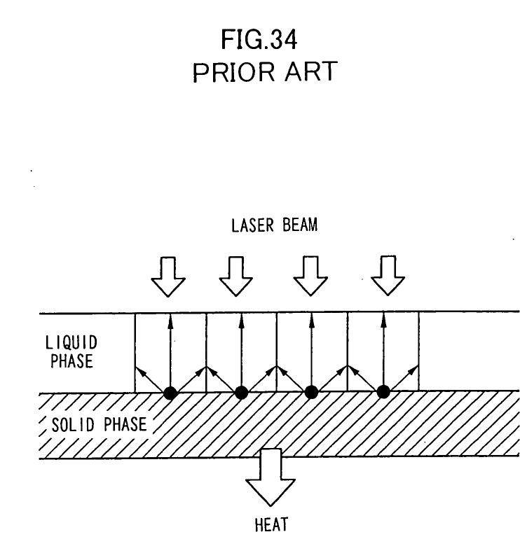

FIG. 35 is an explanatory view showing the state in which a crystal grain is grown by the conventional excimer laser annealing while a remaining a-Si phase becomes an island structure.

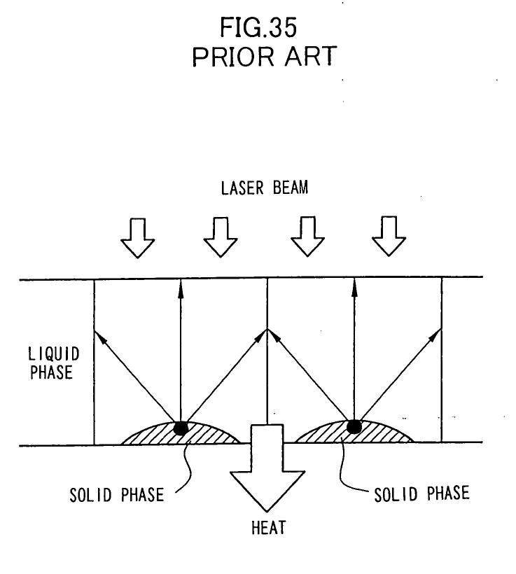

FIG. 36 is an explanatory view showing the state in which, after the a-Si phase is completely melted by the conventional excimer laser annealing, a supercooling state is formed and then the silicon layer is filled with micro-crystal grains.

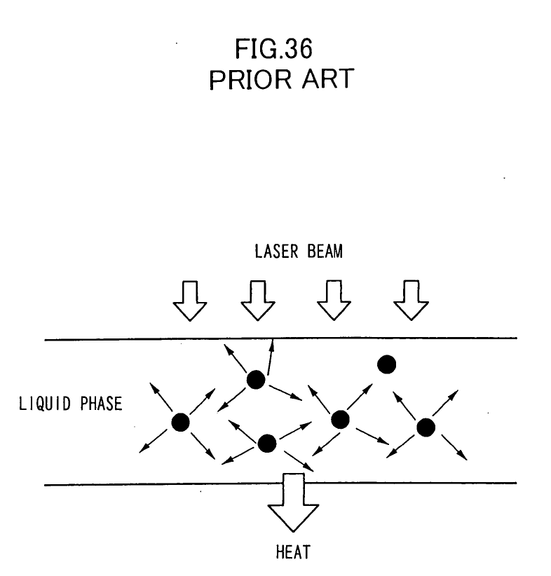

FIG. 37 is an explanatory view qualitatively showing a relationship between laser intensity and a diameter of the crystal grain in the conventional excimer laser annealing.

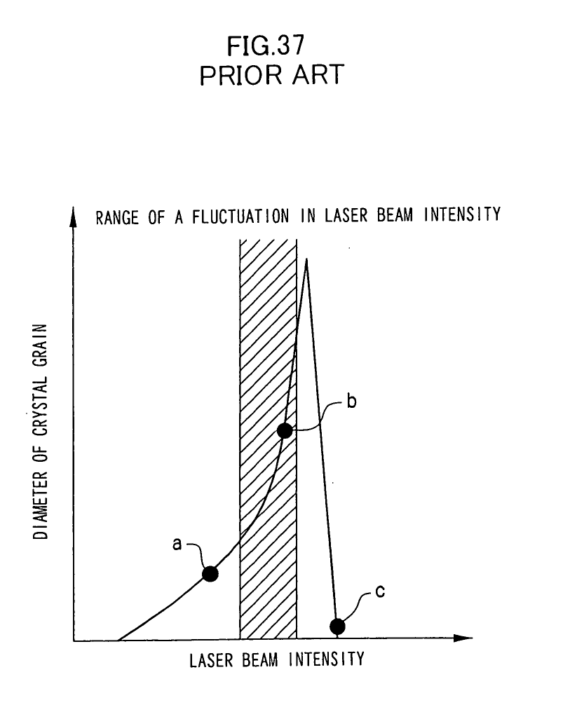

FIG. 38 is an explanatory view showing the state in which a size of a grain boundary is restricted by colliding with the crystal grain from a side opposite to the film thickness in the conventional annealing method in which crystal growth is controlled in a lateral direction.

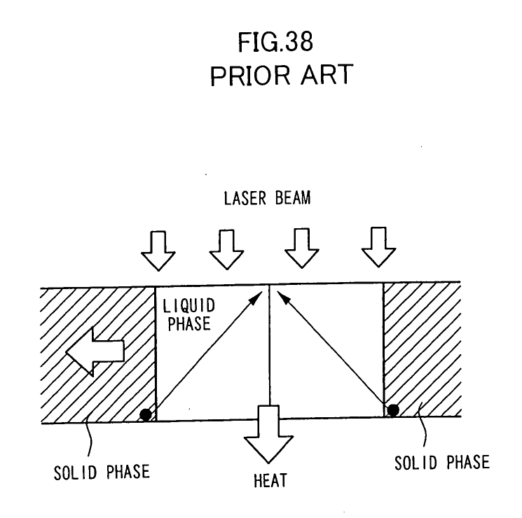

FIG. 39 is an explanatory view showing the state in which a temperature gradient in the depth direction is made flat with the light beam of 532 nm of a Nd:YVO₄ laser and the grain boundary is largely grown in the lateral direction while the solid-liquid interface is formed vertically, in the conventional annealing method in which the crystal growth is controlled in the lateral direction.

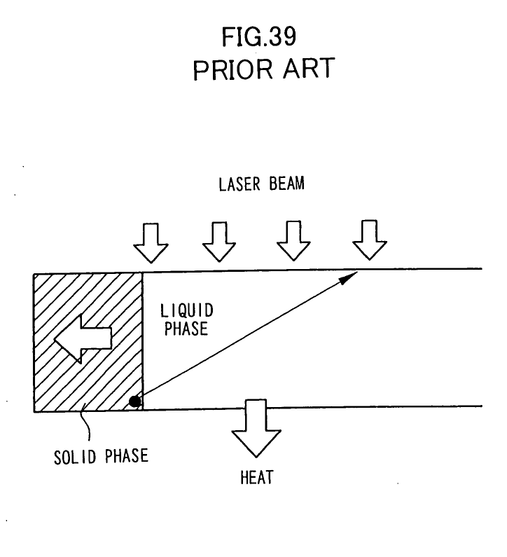

### DETAILED DESCRIPTION OF THE PREFERRED EMBODIMENTS

An embodiment in which the laser annealing apparatus of the present invention is applied to the formation of the low-temperature polysilicon TFT will be described in detail referring to the accompanying drawings.

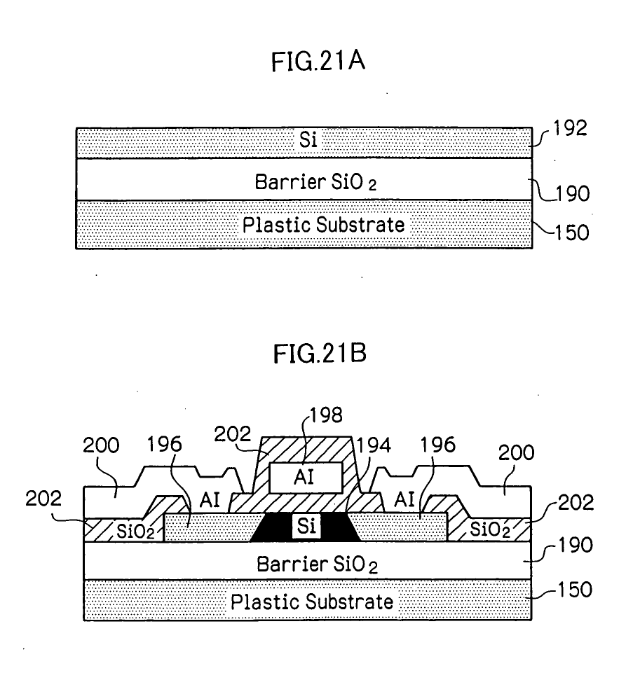

In a process of forming the low-temperature polysilicon TFT in which the laser annealing apparatus according to the embodiment is used, as shown in FIG. 21A, a silicon oxide (SiOₓ) insulating film 190 is deposited on a transparent substrate 150 made of glass or plastic, and an amorphous silicon film 192 is deposited on the SiOₓ insulating film 190.

The amourphous film 192 is polycrystalized by laser annealing to form a polysilicon film. Then, the polysilicon TFT is formed on the transparent substrate 150 via the SiOₓ insulating film 190 by using the photolithography technology. For example, as shown in FIG. 21B, the polysilicon TFT includes a polysilicon gate 194, a polysilicon source/polysilicon drain 196, a gate electrode 198, a source/drain electrode 200, and an interlayer insulating film 202.

[Configuration of Laser Annealing Apparatus]

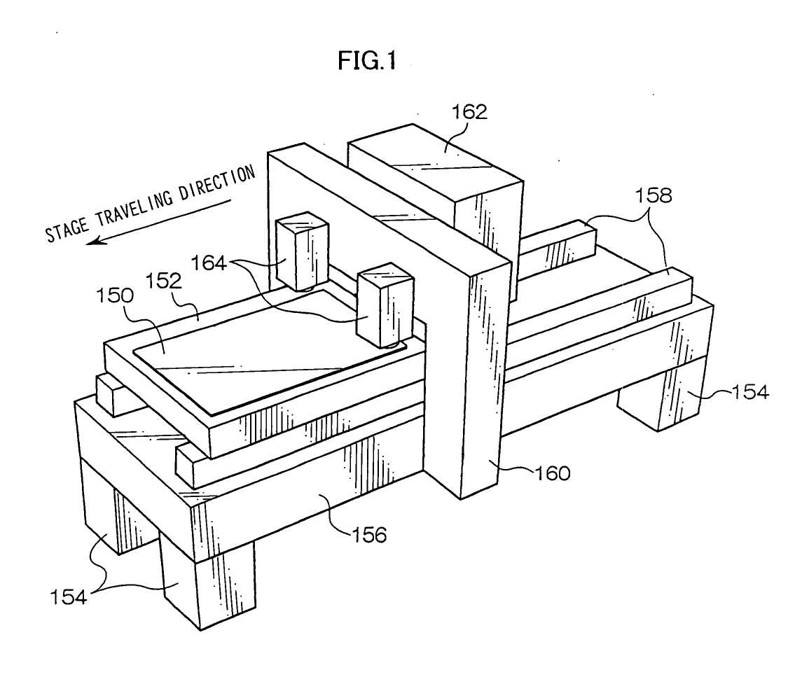

As shown in FIG. 1, the laser annealing apparatus according to the embodiment includes a flat stage 152. The amorphous silicon film is deposited on the transparent substrate 150, which is of the subject to be annealed, and the transparent substrate 150 is absorbed and held on the surface of the flat stage 152. The stage 152 constitutes means for relatively moving the subject to be annealed and the laser beam to scan the laser beam on the subject to be annealed.

Two guides 158 extending along a stage traveling direction are arranged on an upper surface of a thick plate-shaped setting bench 156 supported by four legs 154. The stage 152 is reciprocably supported by the two guides 158 while arranged so that a longitudinal direction of the stage 152 is oriented to the stage traveling direction. A driving device (not shown) for driving the stage 152 along the two guides 158 is provided in the laser annealing apparatus.

In the central portion of the setting bench 156, a U-shaped gate 160 is provided so as to bridge the traveling path of the stage 152. Each end portion of the U-shaped gate 160 is fixed to each side face of the setting bench 156. A scanner 162 is provided on one side across the gate 160, and a plurality of sensors 164 (for example two sensors) which sense a front end and back end of the transparent substrate 150 are provided on the other side. The scanner 162 and the sensors 164 are individually fitted to the gated 160 so as to be fixedly arranged above the traveling path of the stage 152. The scanner 162 and the sensors 164 are connected to a controller (not shown) which controls the scanner 162 and the sensors 164.

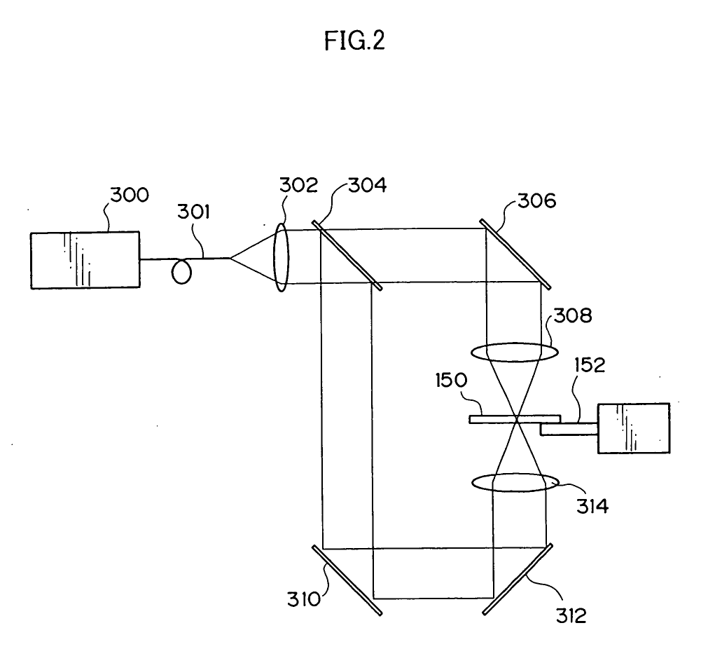

In the laser annealing apparatus, the crystal growth in the lateral direction can be controlled in such a manner that the a-Si film is directly irradiated with the laser beam (405 nm) of the GaN semiconductor laser from both the surface side and the backside of the a-Si film to keep a constant energy absorption distribution generated in the film thickness direction. Therefore, as shown in FIG. 2, means for irradiating the a-Si film with the laser beam from the surface side and backside of the a-Si film is formed in a region from the scanner 162 to the backside of the stage 152.

In the laser beam irradiating means, an optical fiber module light source includes a laser light source 300 and an optical fiber 301. The optical fiber module light source accumulates the laser beam having the wavelength of 405 nm, which is emitted from the GaN semiconductor laser of the laser light source 300, in the optical fiber 301 and outputs the laser beam from an end face of the optical fiber 301.

In the laser beam irradiating means, the laser beam having the wavelength of 405 nm outputted from the end face of the optical fiber 301 in the optical fiber module light source is formed by a beam forming optical system 302 and divided by a beam splitter 304 into the optical path which irradiates the a-Si layer of the subject with the laser beam from one side (for example, the surface) and the optical path which irradiates the a-Si layer with the laser beam from the other side (for example, the backside).

The laser beam transmitted through the beam splitter 304 proceeds on the optical path which irradiates the a-Si layer of the subject with the laser beam from one side (for example, the surface side). The laser beam is reflected by a mirror for beam irradiation 306 toward the direction perpendicular to the substrate 150 on which the a-Si layer is provided. Then, the laser beam is incident to a predetermined position on the surface of the a-Si layer from above while the laser beam is formed in a predetermined beam pattern by a projection lens 308.

On the other hand, the laser beam reflected from the beam splitter 304 proceeds on the optical path, which irradiates the a-Si layer of the subject with the laser beam from the other side (for example, the backside). The laser beam is reflected by a first mirror for beam irradiation 310 and a second mirror for beam irradiation 312 toward the direction perpendicular to the substrate 150. Then, the laser beam is incident to a predetermined position on the surface of the a-Si layer from below while the laser beam is formed in a predetermined beam pattern by a projection lens 314.

In the laser beam irradiating means in the laser annealing apparatus, the optical path is set so that the same irradiation position is irradiated with bath the laser beam with which the a-Si layer is irradiated from the surface side and the laser beam with which the a-Si layer is irradiated from the backside. Further, the same irradiation position is irradiated with both the laser beams at the same time.

In the laser annealing apparatus having the above configuration, the reason why the laser annealing process is effective will be described below.

In the case where the surface of the a-Si layer on the substrate 150 of the substrate is irradiated with the laser beam only from above, the state in which light energy of the incident laser beam having the wave length of 405 nm is absorbed in the a-Si layer having the thickness of 50 nm will be described.

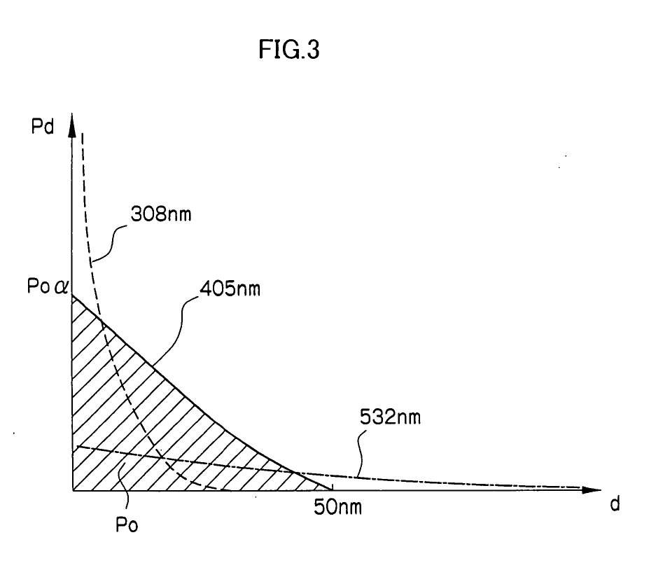

As can be seen from the state of the light energy absorbed in the a-Si layer shown in FIG. 3, the light energy of the laser beam having the wave length of 405 nm incident from above to the a-Si layer having the thickness of 50 nm is substantially completely absorbed in the a-Si layer having the thickness of 50 nm.

In order to determine light energy P_{d} absorbed at a depth d from the surface of the a-Si, an amount of energy absorbed in a thin film layer from the depth d to d+Δd is considered.

The amount of energy absorbed in the range from the surface to the depth d becomes Pₒ exp(−αd), where Pₒ is input energy and α is an absorption coefficient. The amount of energy absorbed in the range from the surface to the depth d+Δd becomes Pₒ exp(−α(d+Δd)).

Therefore, since the amount of energy absorbed in the layer thickness Δd of the a-Si layer becomes Pₒ{ exp(−αd)−exp(−α(d+Δd))}, the following equation holds.

$${lim}_{Δ d \to 0} \frac{{P}_{0} \{ exp ( - α d ) - exp ( - α ( d + Δ d ) ) \}}{d - ( d + Δ d )} = \frac{ⅆ \{ {P}_{0} exp ( - α d ) \}}{ⅆ d} \qquad [ Formular 1 ]$$

Accordingly, the amount of energy P_{d} absorbed at a certain depth d can be expressed by P_{d}=Pₒα exp(−αd).

When the laser beam having the wavelength of 405 nm is incident to the a-Si layer, the state of the light energy absorbed in the a-Si layer can be seen from FIG. 3. That is to say, the absorption starts from the surface of the a-Si layer and decreases exponentially in the film with increasing depth, and the input energy Pₒ is completely absorbed within the film thickness of 50 nm. In FIG. 3, an area surrounded by an X-axis, an Y-axis, and an exponential curve corresponds to the input energy Pₒ.

As described above, in the case where the laser beam having the wavelength of 405 nm is incident to the a-Si layer, since the absorption of the light energy occurs as shown in FIG. 3, the temperature distribution in the a-Si film is also substantially the same as FIG. 3.

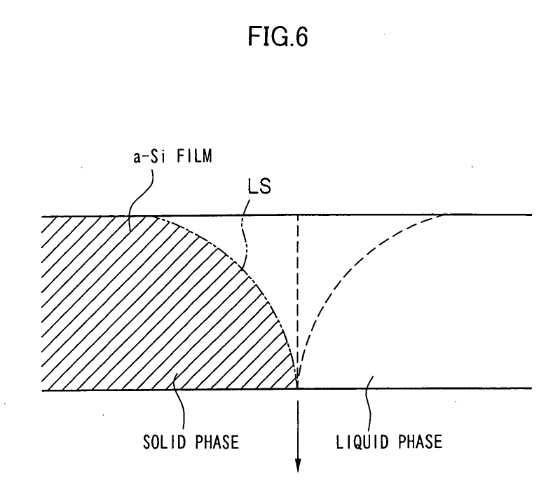

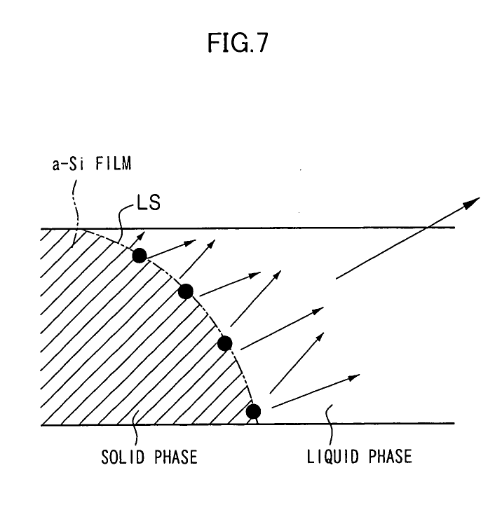

Since the solid-liquid interface also reflects the temperature distribution, the distribution of the solid-liquid interface is not formed vertically, but formed in the oblique shape as shown in FIG. 6. Therefore, since the crystal growth proceeds toward the oblique direction relative to the film thickness direction as shown in FIG. 7, each crystal grain S is grown in the oblique direction, and a length of the crystal growth becomes short due to the restriction of the film thickness.

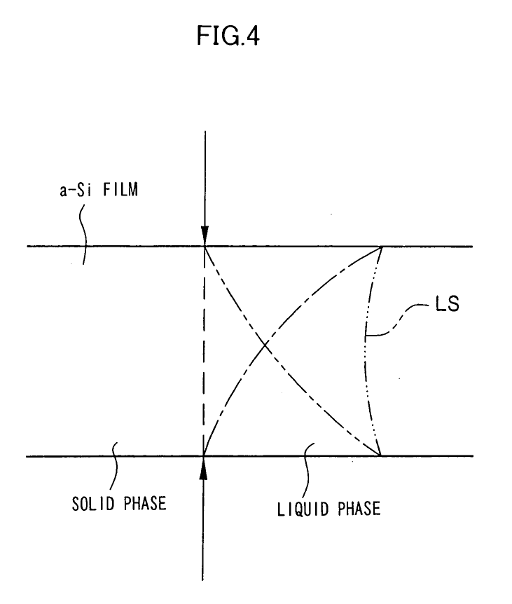

On the other hand, when the laser beam is incident to the surface of the a-Si film from above and below, as shown in FIG. 4, the temperature distribution formed by the laser beam incident to the a-Si film from above becomes the state indicated by a chain double-dashed line and the temperature distribution formed by the laser beam incident to the a-Si film from below becomes the state indicated by an alternate long and short dash line.

The temperature distribution formed by the laser beams incident to the a-Si film from above and below becomes a sum of the temperature distribution formed by the laser beam incident from above and the temperature distribution formed by the laser beam incident from below. The temperature distribution formed by the laser beams incident from above and below is indicated by a chain triple-dashed line in FIG. 4, and the temperature distribution substantially becomes constant to the depth (the thickness direction in the subject to be annealed).

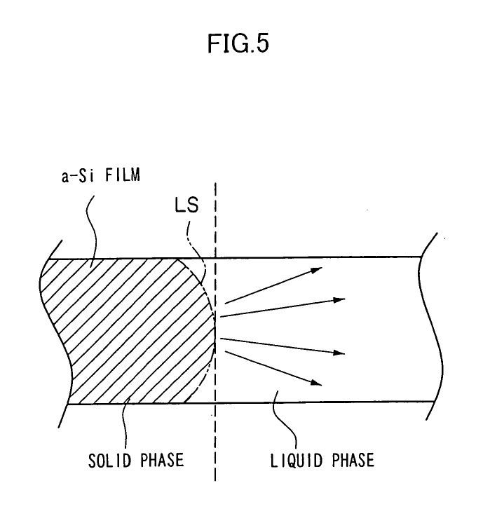

As shown in FIG. 5, a solid-liquid interface LS is formed substantially vertically to the surface if the a-Si film and the crystal growth proceeds in the lateral direction without the restriction of the film thickness, so that the large crystal grain can be formed.

As a result, in the film thickness of about 50 nm, the crystallization of the thin film can be performed by utilizing the input energy without wasting the input energy, the solid-liquid interface LS is vertically formed to realize the crystal growth in the lateral direction without the restriction of the film thickness of the a-Si layer, and the large crystal grain can be formed. That is to say, the contradict demands of the vertical formation of the solid-liquid interface and the crystallization of the thin film, which are effective to the formation of the large crystal grain, are compatible with each other.

Next a condition in which the laser annealing process is well performed by the laser annealing apparatus of the invention will be described.

The condition in which the laser annealing process is well performed is defined a product of the film thickness d and the absorption coefficient α(λ) when the light beam is absorbed in the film-shaped subject.

In performing the annealing process by irradiating the film-shaped subject with the light beam from the surface and backside of the subject, when the light beam having the input energy Pₒ passes through the film thickness d having the absorption coefficient α(λ), the energy P is expressed by P=Pₒ exp(−α(λ)·d). Accordingly, the input energy absorbed at the film thickness d becomes P_{d}=Pₒ(1−exp(−α(λ)d)).

An absorption index η_{abs} can be expressed by the following equation.

η_{abs}=1−exp(−α(λ)d) (1)

The presence of the effective absorption area of the light energy inputted into the film thickness (a condition such that 99% of inputted light energy is absorbed) is defined by the following equation (2). Further, the effective utilization of the inputted light energy is defined by the following equation (3).

η_{abs}=0.99 (2)

η_{abs}=0.4 (3)

The equations (1) and (2) lead to exp(−α(λ)d)=0.01.

Therefore, the following equation (4) is obtained.

α(λ)·d=4.6 (4)

The equations (2) and (3) lead to exp(−α(λ)d)=0.6.

Therefore, the following equation (5) is obtained.

α(λ)·d≅0.5 (5)

Accordingly, the range, led by equation (4), in which the effect of the both-side irradiation is effectively generated, is defined by the following expression (6).

α(λ)·d≦4.6 (6)

On the condition that the energy loss is in the permissible range, such that on the condition that the annealing process is performed so as to be economically feasible by utilizing more than 40% of the light energy of the laser beam, the range, led by equations (4) and (5), in which the energy loss is in the permissible range and the effect of the both-side irradiation is effectively generated is defined by the following equation (7).

0.5≦α(λ)·d≦4.6 (7)

[Other Configurations of Laser Annealing Apparatus]

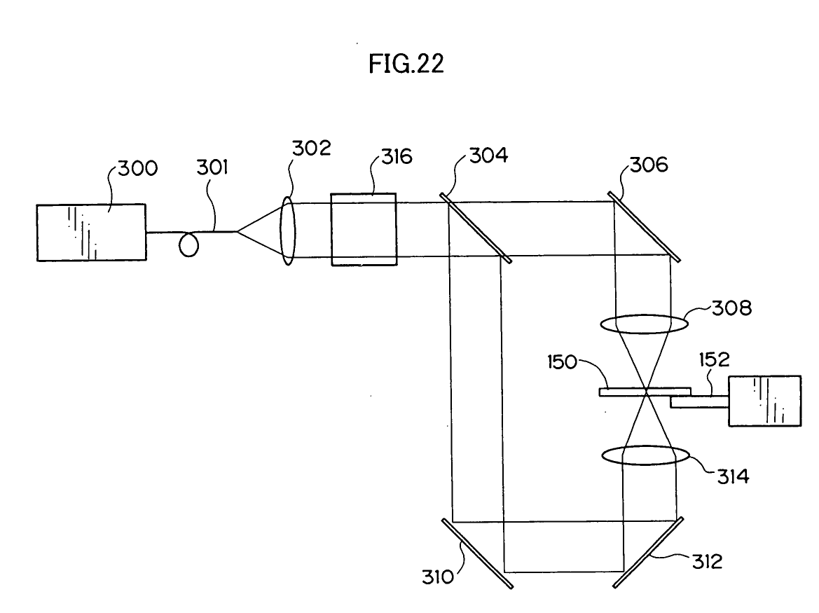

The configuration of the laser beam irradiating means in the laser annealing apparatus shown in FIG. 22 will be described below.

In the laser beam irradiating means shown in FIG. 22, the laser beam outgoing from the end face of the optical fiber 301 is modulated into the light beam having desired beam intensity by utilizing the beam forming optical system 302 and a spatial light modulator 316. Other constituent components are the same as the laser beam irradiating means shown in FIG. 2.

In the laser beam irradiating means in the laser annealing apparatus shown in FIG. 22, the spatial light modulator 316 can be formed by a digital micromirror device (DMD) which is of the spatial light modulator modulating the incident light beam in each pixel according to data to form a predetermined spatial distribution. The spatial light modulator (DMD) 316 is connected to a controller (not shown) including a data processing unit and a mirror driving control unit. In the data processing unit of the controller, a control signal, which drives and controls each micromirror in the area to be controlled in each spatial light modulator 316 is generated on the basis of the inputted data. The data is one which density of each pixel is expressed in the binary value (presence or absence of dot recording). In the mirror driving control unit, an angle of a reflection plane of each micromirror is controlled in each spatial light modulator 316 on the basis of the control signal generated by the data processing unit.

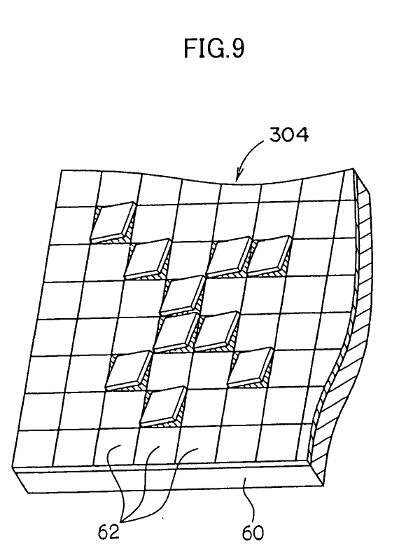

As shown in FIG. 9, the spatial light modulator (DMD) 316 is a mirror device in which micromirrors 62 are arranged and supported by supports on an SRAM memory (memory cell) 60 and many micromirrors (for example, 600 pieces by 800 pieces) constituting the pixel are arrayed in the form of a matrix. The micromirror 62 supported by the support is provided at an uppermost portion of each pixel, and a material having high reflectance such as aluminum are deposited on the surface of the micromirror 62. The reflectance of the micromirror is not lower than 90%. The SRAM cell 60 of CMOS silicon gate manufacture by a usual manufacturing line of a semiconductor memory is arranged immediately below the micromirrors 62 through the support including a hinge and a yoke, and the spatial light modulator (DMD) 304 is formed in monolithic (integral type).

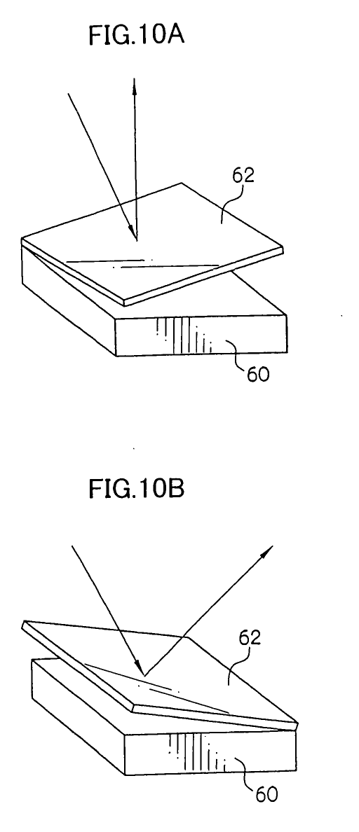

When a digital signal is written in the SRAM cell 60 of the spatial light modulator (DMD) 316, the micromirror 62 supported by the support is inclined within the range of ±α degrees (for example, ±10 degrees) about a diagonal of the micromirror 62 relative to the substrate side on which the spatial light modulator (DMD) 316 is arranged. FIG. 10A shows the on-state in which the micromirror 62 is inclined by +α degrees and FIG. 10B shows the off-state in which the micromirror 62 is inclined by −α degrees. The light incident to the spatial light modulator (DMD) 316 is reflected toward the direction in which each micromirror 62 is inclined by controlling the inclination of the micromirror 62 in each pixel of the spatial light modulator (DMD) 316 according to the data signal as shown in FIGS. 10A and 10B.

FIGS. 10A and 10B show examples of the state in which the micromirror 62 is controlled to +α degrees or −α degrees while a part of the spatial light modulator (DMD) 316 is expanded. The on-off control of each micromirror 62 is performed by the controller (not shown) connected to the spatial light modulator (DMD) 316. A light absorber (not shown) is arranged in the direction in which the light beam is reflected by the micromirror in the off-state.

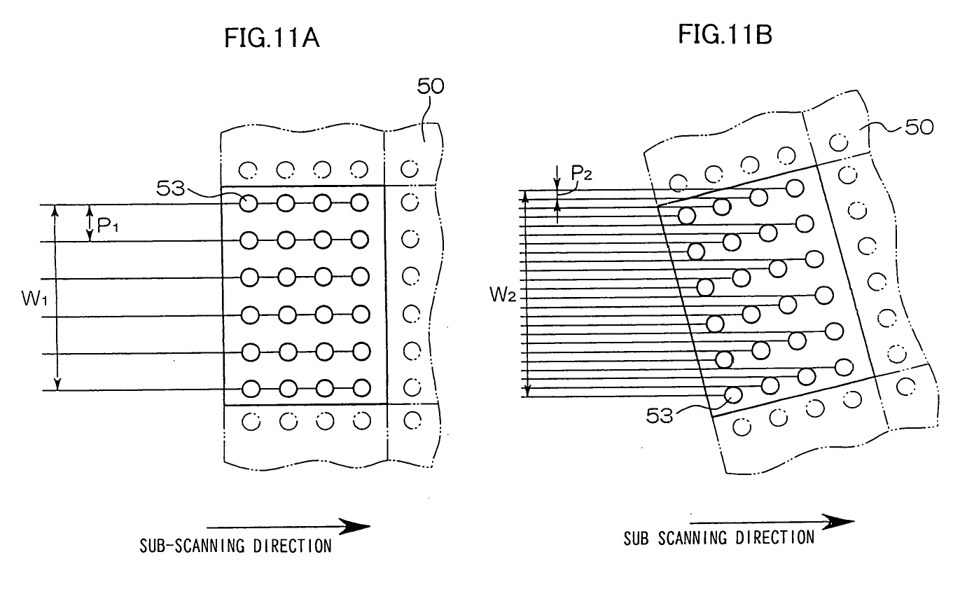

It is preferable that the spatial light modulator (DMD) 316 is slightly obliquely arranged so that a short side of the spatial light modulator (DMD) 316 and a sub-scanning direction form a predetermined angle θ (for example, 1° to 5°). FIG. 11A shows a scanning trajectory of a reflected light figure (irradiation beam) 53 generated by each micromirror in the case where the spatial light modulator (DMD) 316 is not inclined, and FIG. 11B shows the scanning trajectory of the irradiation beam 53 in the case where the spatial light modulator (DMD) 316 is inclined.

In the spatial light modulator (DMD) 316, many sets (for example, 600 sets) of micromirror columns in which many micromirrors (for example, 800 pieces) are arrayed in the direction of a long side are arrayed in the direction of the short side. As shown in FIG. 11B, a pitch P₂ of the scanning trajectory (scanning line) of the irradiation beam 53 by each micromirror is narrowed by inclining the spatial light modulator (DMD) 316, compared with a pitch P₁ of the scanning line in the case where the spatial light modulator (DMD) 316 is not inclined, so that the resolution can be remarkably improved. On the other hand, since the inclination angle of the spatial light modulator (DMD) 316 is minute, a scanning width W₂ in the case of the inclined spatial light modulator (DMD) 316 is substantially equal to a scanning width W₁ in the case of the not-inclined spatial light modulator (DMD) 304.

The multiple laser beam irradiation of the same scanning line (multiple exposures) is performed by the different micromirror columns. As a result of the multiple exposures, a laser beam irradiation position can be finely controlled in micro unit and the fine annealing can be realized. Joints between the plurality of laser light sources 300 arrayed in a main scanning direction can be connected without seam by controlling finely the laser beam irradiation position.

Instead of the inclination of the spatial light modulator (DMD) 316, the same effect can be also obtained by shifting each micromirror column in the direction orthogonal to the sub-scanning direction to form a staggered arrangement.

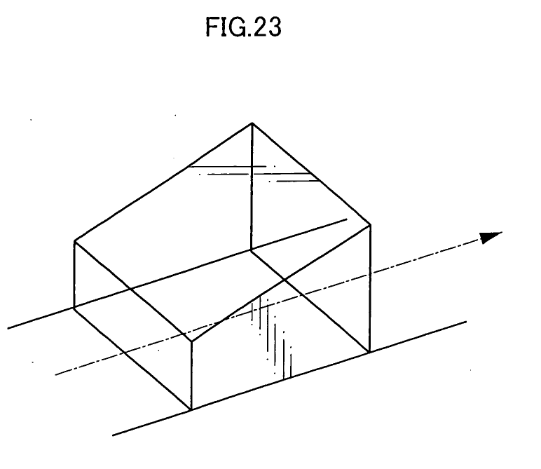

In the laser beam irradiating means in the laser annealing apparatus, the light energy distribution projected to a microscopic striped-shaped region of the a-Si film on the substrate 150 is adjusted by utilizing the spatial light modulator (DMD) 316 so that, as shown in FIG. 23, a gradient of the light energy intensity is strong on the front end side in the conveying direction of the substrate 150 and gradually decreased as the distribution proceeds to the back end side in the conveying direction. As a result, the ideal in-depth temperature distribution of the a-Si film can be realized.

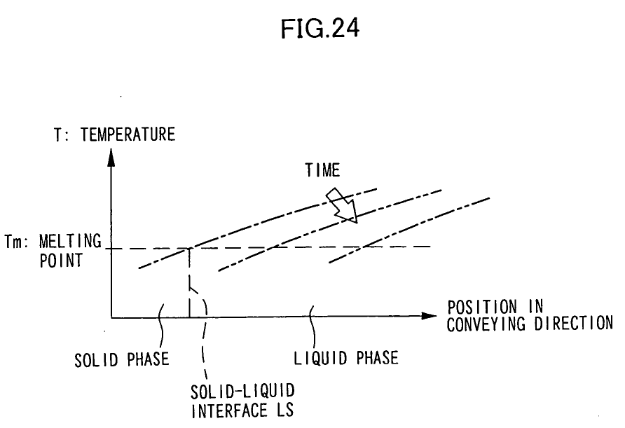

That is to say, in the laser beam irradiating means, as indicated by the alternate long and short dash line in FIG. 24, in the region in a fused state ranging from a fusion start position on the front end side in the conveying direction (upstream side of in the conveying direction) where the a-Si film is irradiated with the laser beam to start the fusion to the position of the solid-liquid interface LS on the back end side in the conveying direction (downstream side of in the conveying direction), the temperature gradient can be controlled so that the temperature is smoothly decreased from the fusion start position to the position of the solid-liquid interface LS, in such a manner that the light energy distribution to the a-Si film is adjusted by utilizing the spatial light modulator (DMD) 316 so as to be strong on the front end side in the conveying direction of the substrate 150 and to be gradually decreased as the distribution proceeds to the back end side in the conveying direction as shown in FIG. 23.

As described above, in the case of heating control exhibiting the temperature gradient in which the temperature is smoothly decreased from the fusion start position to the position of the solid-liquid interface LS, silicon oxide in the a-Si film fused by the laser beam can be controlled so that the crystal is always grown from the crystal nucleus generated in the solid-liquid interface LS.

Therefore, it is possible to prevent the interruption of the formation of the large crystal grain, which is caused by the crystal growth from the crystal nucleus generated in the region partially cooled between the fusion start position and the position of the solid-liquid interface LS (region except the solid-liquid interface LS).

In the heating control, even if the region in the a-Si film fused by the laser beam is cooled by various factors, it is desirable that the temperature gradient is set so that the crystal nucleus is not generated in the region except the solid-liquid interface LS.

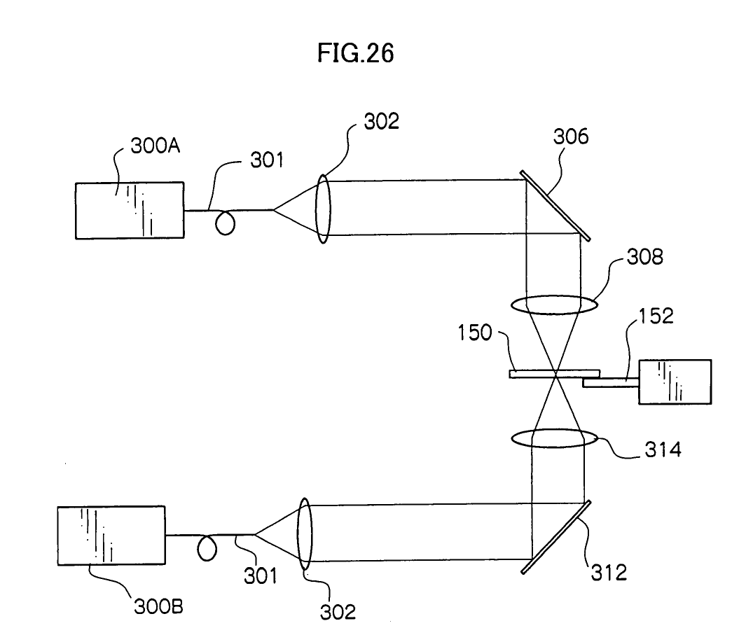

The configuration of the laser beam irradiating means in the laser annealing apparatus shown in FIG. 26 will be described below.

In the laser beam irradiating means shown in FIG. 26, a first optical path which irradiates the a-Si layer of the subject with the laser beam from one side (for example, the surface) and a second optical path which irradiates the a-Si layer with the laser beam from the other side (for example, the backside) are separately formed by using two laser light sources 300A and 300B.

In the laser beam irradiating means, each optical fiber module light sources includes each of the two laser light sources 300A and 300B and the optical fiber 301. The optical fiber module light source accumulates the laser beam having the wavelength of 405 nm emitted from the GaN semiconductor laser in the optical fiber 301 and outputs the laser beam from the end face of the optical fiber 301.

In the laser beam irradiating means using the two laser light sources 300A and 300B show in FIG. 26, the optical path which irradiates the a-Si layer, which is of the subject to be irradiated, with the laser beam from one side (for example, the surface) is configured so that the laser beam having the wavelength of 405 nm outputted from the end face of the optical fiber 301 in one of the optical fiber module light sources is formed by the beam forming optical system 302 and reflected by the mirror for beam irradiation 306 toward the direction perpendicular to the substrate 150 on which the a-Si layer is provided. Then, the laser beam is incident to a predetermined position on the surface of the a-Si layer from above, while the laser beam is formed in a predetermined beam pattern by the projection lens 308.

The optical path which irradiates the a-Si layer of the subject with the laser beam from the other side (for example, the backside) is configured so that the laser beam having the wavelength of 405 nm outputted from the end face of the optical fiber 301 in the other optical fiber module light source is formed by the beam forming optical system 302 and reflected by the mirror for beam irradiation 312 toward the direction perpendicular to the substrate 150 on which the a-Si layer is provided. Then, the laser beam is incident to a predetermined position on the surface of the a-Si layer from below, while the laser beam is formed in a predetermined beam pattern by the projection lens 314.

Other constituent components, operations, and effects except the above-described constituent components, operations, and effects in the laser beam irradiating means shown in FIG. 26 are the same as the laser beam irradiating means shown in FIG. 2.

In the laser beam irradiating means using the two laser light sources 300A and 300B shown in FIG. 26, the solid-liquid interface can be stood substantially perpendicular to the film surface by adjustment of the wavelength, modulation, and the change and adjustment of laser output.

Then, in the laser beam irradiating means using the two laser light sources 300A and 300B shown in FIG. 26, the laser beam irradiating means, which is configured such that one of the surfaces of the subject to be annealed is irradiated from one direction with the laser beam emitted from the laser light source 300A while the other surface is irradiated from the other direction with the laser beam emitted from the laser light source 300B having the wavelength different from that of the laser light source 300A and the laser output is adjusted, will be described.

In this case, for example, the laser light source 300A is formed by the optical fiber module light source which accumulates the laser beam having the wavelength of 460 nm emitted from the GaN semiconductor laser in the optical fiber 301 and outputs the laser beam, and the laser light source 300B is formed by the optical fiber module light source which accumulates the laser beam having the wavelength of 400 nm emitted from the GaN semiconductor laser in the optical fiber 301 and outputs the laser beam.

Since the absorption coefficient of the laser beam having the wavelength of 460 nm emitted from the laser light source 300A to a-Si is 1×10⁵ cm⁻¹, a rate of absorption of the laser beam in the film thickness of 50 nm(=5×10⁻⁶ cm) becomes 1−exp(1×10⁵×5×10⁻⁶)=1-exp(−0.5)=0.4.

Since the absorption coefficient of the laser beam having the wavelength of 400 nm emitted from the laser light source 300B to a-Si is 5×10⁵ cm⁻¹, a rate of absorption of the laser beam in the film thickness of 50 nm becomes 1-exp(5×10⁵×5×10⁻⁶)=1-exp(2.5)=0.92.

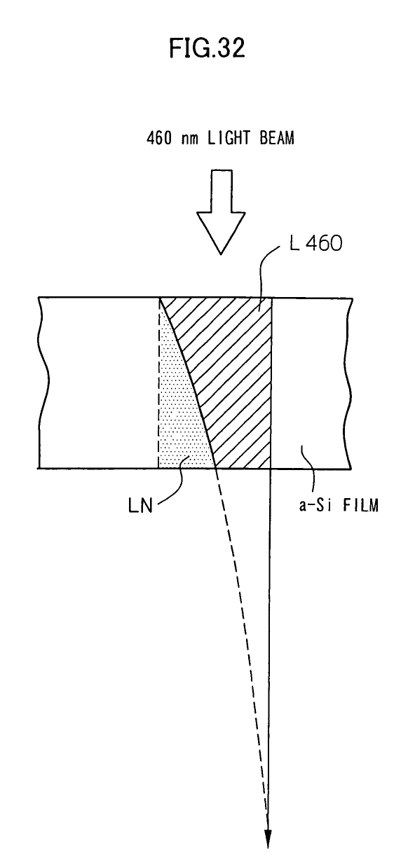

In the case where the laser beam having the wavelength of 460 nm emitted from the laser light source 300A is inputted to one side of the substrate 150, the state in which the light energy is absorbed in the a-Si film becomes an absorption energy distribution LN460 in the film of the light beam having the wavelength of 460 nm, which is shown in FIG. 32 by the hatched area.

As can be seen from FIG. 32, when an absorption energy distribution LN in the film which is shown in FIG. 32 by a halftone area is added to the absorption energy distribution LN460 in the film, the absorption energy in the film thickness direction of the a-Si film can be uniformed.

That is to say, the absorption energy distribution LN in the film is the absorption energy in the a-Si film which is required to cause the absorption energy distribution in the a-Si film to make constant in the film thickness direction (depth direction).

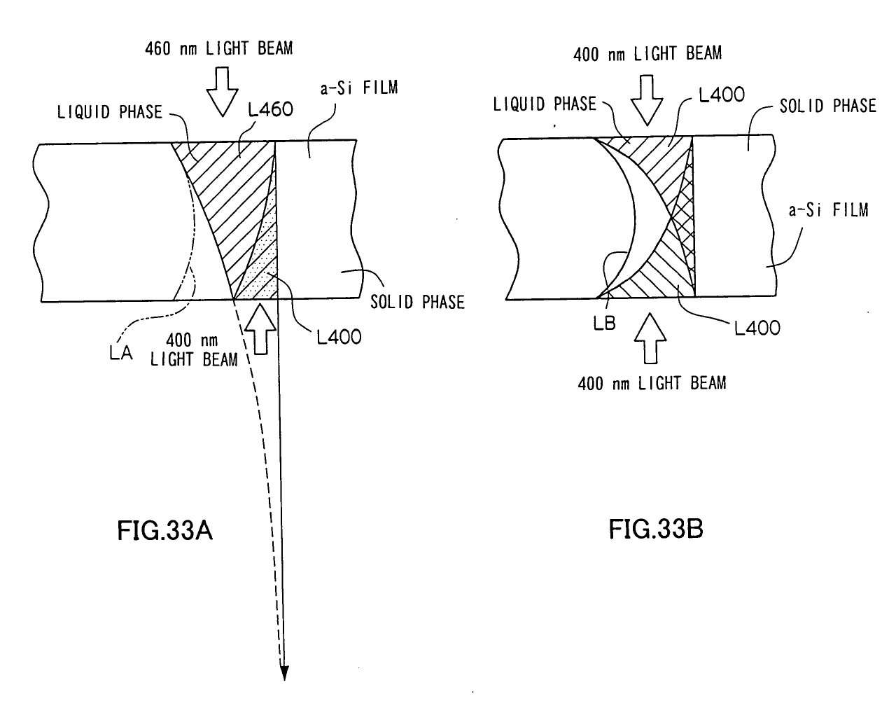

Therefore, as shown in FIG. 33A, the laser beam having the wavelength of 400 nm emitted from the laser light source 300B is inputted by the amount of energy corresponding to the absorption energy distribution LN in the film from the direction opposite to the laser beam having the wavelength of 460 nm, and an absorption energy distribution LN400 in the film is formed by the laser beam having the wavelength of 400 nm. In FIG. 33A, the absorption energy distribution LN400 in the film is shown by the hatched halftone area.

Then, a total absorption energy distribution LA in the film is formed as the sum of the energy distributions of the absorption energy distribution LN460 in the film and the absorption energy distribution LN400 in the film.

For comparison, when the absorption energy distributions LN400 (hatched areas in FIG. 33B) in the film is formed by irradiating the film with the laser beams having the wavelengths of 400 nm from both the sides, a total absorption energy distribution LB in the film as the sum of the energy distributions is obtained as shown in FIG. 33B.

When the total absorption energy distribution LA in the film shown in FIG. 33A and the total absorption energy distribution LB in the film shown in FIG. 33B are compared with each other, the absorption energy distribution in the film thickness direction is more uniform in the total absorption energy distribution LA than in the total absorption energy distribution LB.

Accordingly, more effective annealing can be realized by adjusting the irradiation wavelength of the laser beam and the laser output concerning each irradiation direction in the both-side irradiation.

It is also possible that the adjustment of the laser output is substituted for the adjustment of the amount of energy inputted by the modulation of the laser beam.

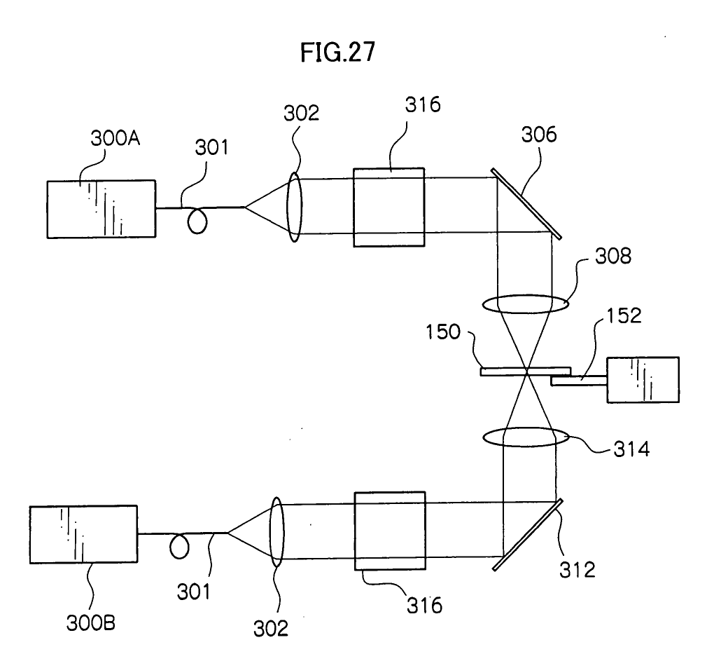

The configuration of the laser beam irradiating means in the laser annealing apparatus shown in FIG. 27 will be described below.

In the laser beam irradiating means shown in FIG. 27, the first optical path irradiating the a-Si layer which is of the subject with the laser beam from one of the surfaces (for example, from the surface) and the second optical path irradiating the a-Si layer with the laser beam from the other surface (for example, from the backside) are separately formed by utilizing two laser light sources 300A and 300B, and the laser beam outgoing from the laser light sources 300A and 300B through each optical fiber 301 is configured to be modulated into the desired beam intensity by utilizing the beam forming optical system 302 and the spatial light modulator 316. Other constituent components are the same as the laser beam irradiating means shown in FIG. 2.

In the laser beam irradiating means having the configuration shown in FIG. 27, it is possible to have both the operations and advantages obtained by each of the laser beam irradiating means shown in FIGS. 2, 22, and 26.

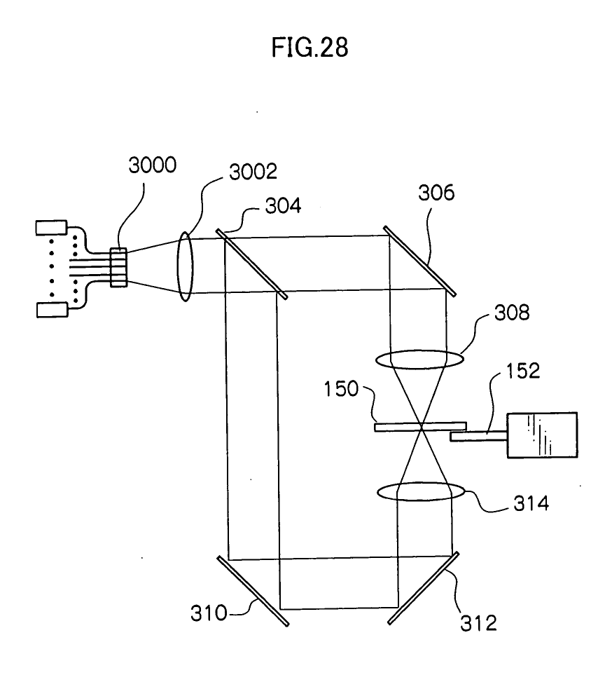

The configuration of the laser beam irradiating means in the laser annealing apparatus shown in FIG. 28 will be described below.

The laser beam irradiating means shown in FIG. 28 is configured to include a fiber array light source 3000 as the laser light source 300 and a beam forming optical system 3002 which forms the laser beam emitted from laser beam outgoing units arrayed in line or in the plurality of lines along the main scanning direction orthogonal to the sub-scanning direction into the light beam having the desired beam intensity. Other constituent components are the same as the laser beam irradiating means shown in FIG. 2.

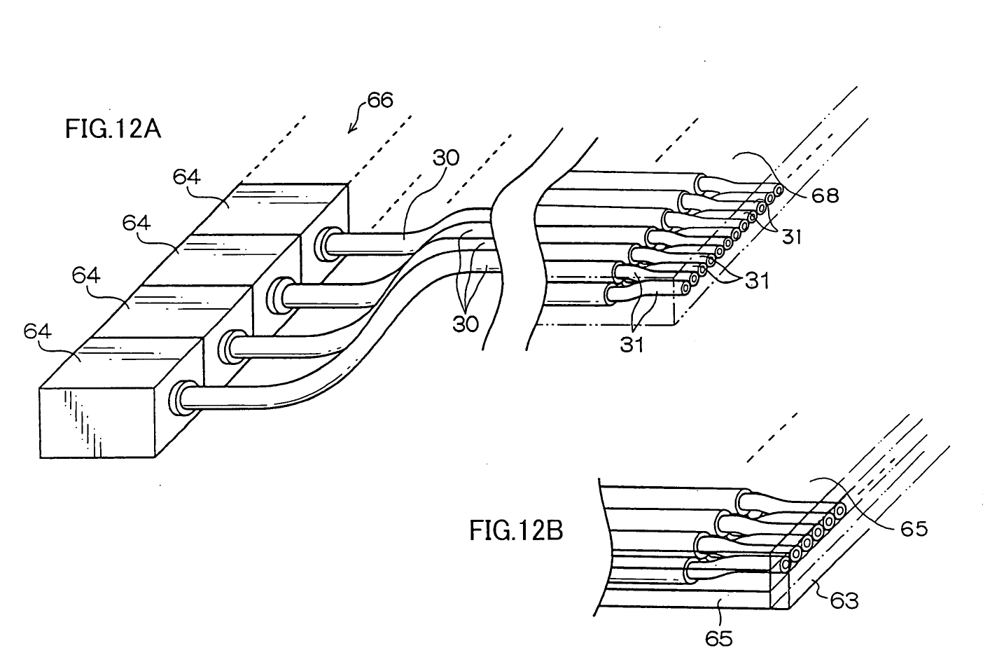

As shown in FIG. 12A, the fiber array light source 3000 includes many laser modules 64 and each laser module 64 is connected to one end of a multi-mode optical fiber 30. The other end of the multi-mode optical fiber 30 is connected to an optical fiber 31. A core diameter of the optical fiber 31 is equal to that of the multi-mode optical fiber 30 and a clad diameter of the optical fiber 31 is smaller than that of the multi-mode optical fiber 30. A laser-outgoing unit 68 is configured by arraying outgoing end portions (light emission point) of the optical fibers 31 in line along the main scanning direction orthogonal to the sub-scanning direction. It is also possible to array the light emission points in plural columns along the main scanning direction.

As shown in FIG. 12B, the outgoing end portion of the optical fiber 31 is fixed while the optical fiber is sandwiched by two support plates 65 whose surfaces are flat. On the light-outgoing side of the optical fiber 31, a transparent protective plate 63 made of glass or the like is arranged in order to protect an end face of the optical fiber 31. It is possible that the protective plate 63 is arranged so as to come into close contact with the end face of the optical fiber 31, and it is also possible that the protective plate 63 is arranged so that the end face of the optical fiber 31 is sealed. In the outgoing end portion of the optical fiber 31, light density is high, dust is easy to gather, and degradation is easy to occur. However, arrangement of the protective plate 63 can prevent the dust from adhering to the end face and delay progression of the degradation.

In this example, since the outgoing ends of the optical fiber 31 having the smaller clad diameter are arrayed in line without gap, the multi-mode optical fiber 30 is stacked between two multi-mode optical fibers 30 adjacent to each other in the region where the clad diameter is larger, and the outgoing ends of the optical fibers 31 connected to the stacked multi-mode optical fiber 30 are arrayed so as to be sandwiched between two multi-mode optical fibers 30 adjacent to each other in the region where the clad diameter is larger.

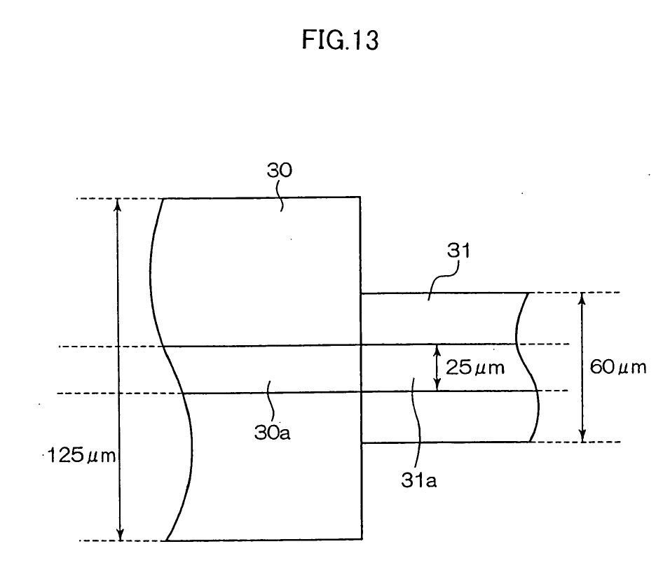

For example, as shown in FIG. 13, the above optical fiber can be obtained in such a manner that the optical fiber 31 having the smaller clad diameter and the length of 1 to 30 cm is coaxially connected to the front end portion on the laser beam outgoing side of the multi-mode optical fiber 30 having larger clad diameter. In the two optical fibers, the incident end face of the optical fiber 31 is fused and connected to the outgoing end face of the multi-mode optical fiber 30 so that central axes of the both optical fibers correspond to each other. As described above, the diameter of a core 3la of the optical fiber 31 is equal to the diameter of a core 30a of the multi-mode optical fiber 30.

It is also possible that the short optical fiber, in which the optical fiber having the smaller clad diameter is fused to the short optical fiber having the larger clad diameter, is connected to the outgoing end of the multi-mode optical fiber 30 through a ferrule or an optical connector. When the optical fiber having the smaller diameter is destroyed, exchange of the front end portions becomes easy by connecting detachably the optical fibers with the optical connector or the like, and cost required for maintenance of an irradiation head can be decreased. Hereinafter sometimes the optical fiber 31 is referred to as the outgoing end portion of the multi-mode optical fiber 30.

Any one of a step-index optical fiber, grated-index optical fiber, and a composite optical fiber can be used as the multi-mode optical fiber 30 and the optical fiber 31. For example, the step-index optical fiber made by Mitsubishi Cable Industries, Ltd. can be used. In the embodiment, the multi-mode optical fiber 30 and the optical fiber 31 are the step-index optical fiber. In the multi-mode optical fiber 30, the clad diameter is 125 μm, the core diameter is 25 μm, NA is 0.2 and the transmittance of an incident end face coat is not lower than 99.5%. In the optical fiber 31, the clad diameter is 60 μm, the core diameter is 25 μm, and NA is 0.2.

Usually, in the laser beam having the wavelength of the infrared range, propagation loss is increased as the clad diameter of the optical fiber is decreased. Accordingly, the preferable clad diameter is determined according to the wavelength range of the laser beam. However, the propagation loss is decreased as the wavelength is shortened. In the laser beam having the wavelength of 405 nm emitted from the GaN-based semiconductor laser, the propagation loss is not substantially increased, even if the thickness of the clad, i.e. (clad diameter−core diameter)/2 is decreased to about 0.5 compared with the case in which the infrared light beam having the wavelength range of 800 nm is transmitted and to about 0.25 compared with the case in which the infrared light beam for optical communication having the wavelength range of 1.5 μm. Accordingly, it is possible that the clad diameter is decreased as small as 60 μm.

Further, the clad diameter of the optical fiber 31 is not limited to 60 μm. Although the clad diameter of the optical fiber used for the conventional fiber light source is 125 μm, since a focal depth becomes deeper as the clad diameter is decreased, it is preferable that the clad diameter of the multi-mode optical fiber is not more than 80 μm, it is more preferable that the clad diameter is not more than 60 μm, and it is further more preferable that the clad diameter is not more than 40 μm. On the other hand, since it is necessary that the core diameter be at least in the range of 3 to 4 μm, it is preferable that the clad diameter of the optical fiber 31 is not less than 10 μm.

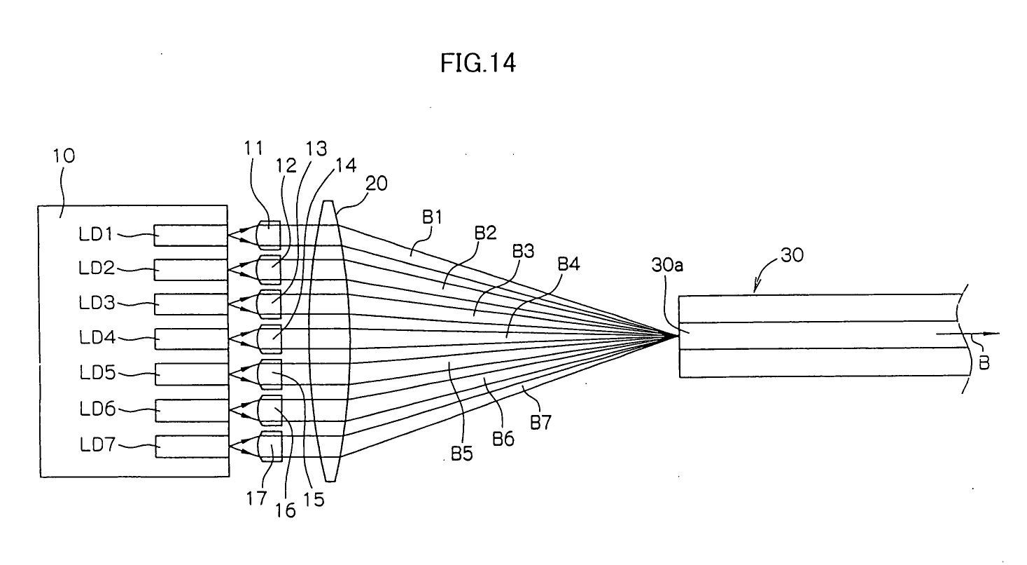

The laser module 64 includes a multiplex laser light source (fiber light source) shown in FIG. 14. The multiplex laser light source includes a plurality of lateral multi-mode or single-mode GaN-based tip semiconductor lasers LD1, LD2, LD3, LD4, LD5, LD6, and LD7 which are arrayed and fixed onto a heat black 10, collimator lenses 11, 12, 13, 14, 15, 16, and 17 which are provided corresponding to each of the GaN-based semiconductor lasers LD1 to LD7, a condenser lens 20, and one multi-mode optical fiber 30. The number of the semiconductor lasers is not limited to seven. For example, it is possible that the 20 laser beams of the semiconductor laser are incident to the multi-mode optical fiber in which the clad diameter is 60 μm, the core diameter is 50 μm, and NA is 0.2. The light amount required for the irradiation head can be realized and the number of optical fibers can be further decreased.

In the GaN-based semiconductor lasers LD1 to LD7, all oscillation wavelengths are the same (for example, 405 nm) and all maximum outputs are also the same (for example, 100 mW in the multi-mode laser and 30 mW in the single mode laser). It is also possible that the laser, which has the oscillation wavelength except 405 nm in the range from 350 nm to 450 nm, is used as the GaN-based semiconductor lasers LD1 to LD7. The preferable wavelength range is described later.

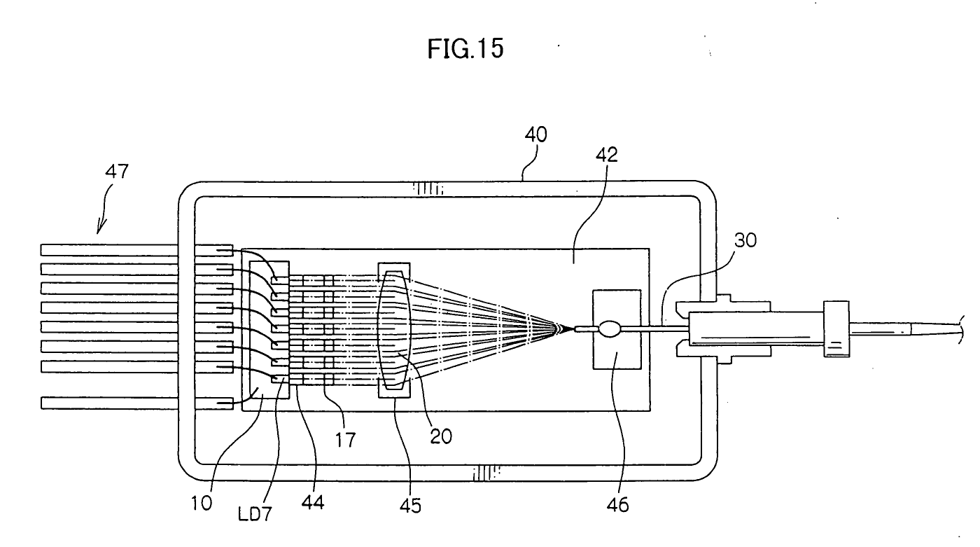

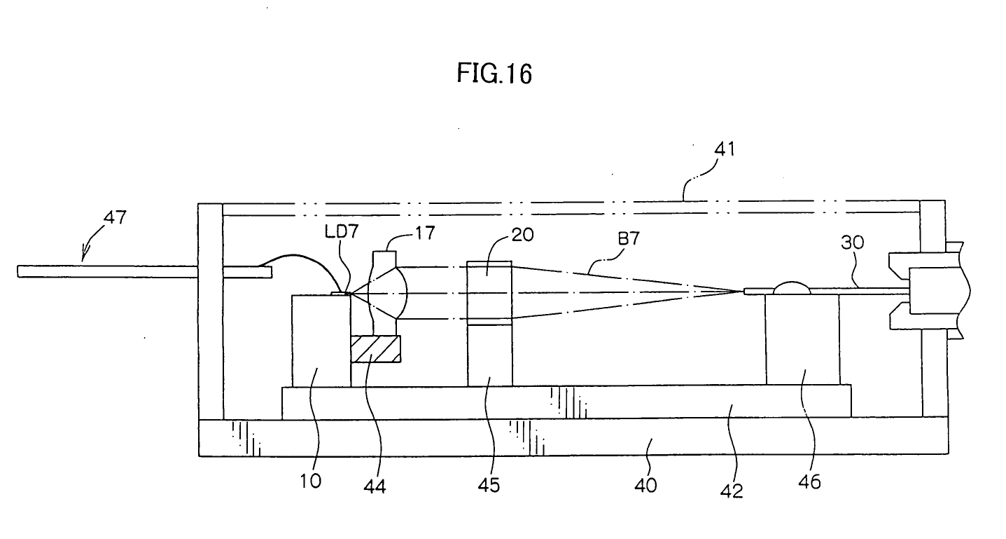

As shown in FIGS. 15 and 16, the above multiplex laser light source and other optical elements are stored in a box-shaped package 40 whose upper side is opened. The package 40 includes a package top 41, which is formed so as to close the opening of the package 40. The multiplex laser light source is hermetically sealed in a closed space formed by the package 40 and the package to 41 in such a manner that sealing gas is introduced after deaeration and the opening of the package 40 is closed by the package top 41.

A base plate 42 is fixed to a bottom of the package 40. A heat block 10, a condenser lens holder 45 which holds the condenser lens 20, a fiber holder 46 which holds the incident end face of the multi-mode optical fiber 30 are fitted to an upper surface of the base plate 42. The outgoing end face of the multi-mode optical fiber 30 is extracted outside the package from the opening formed in a wall surface of the package 40.

A collimator lens holder 44 is fitted to a side face of the heat block 10, and the collimator lenses 11 to 17 are held in the collimator lens holder 44. The opening is formed in a side wall surface of the package 40, and leads 47 for supplying driving current to the GaN-based semiconductor lasers LD1 to LD7 are extracted outside the package through the opening.

In FIG. 16, in order to avoid complication of the figure, only the GaN-based semiconductor laser LD7 is numbered in the plurality of GaN-based semiconductor lasers, and only the collimator lens 17 is numbered in the plurality of collimator lenses.

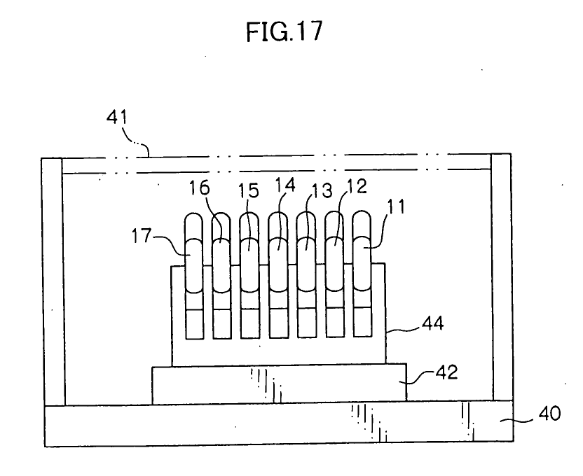

FIG. 17 shows a front face of apart to which the collimator lenses 11 to 17 is fitted. Each of the collimator lenses 11 to 17 is formed in the elongated shape in which the area including the optical axis of an a spheric circular lens is cut away by parallel planes. The elongated-shaped collimator lens can be formed by molding resin or optical glass. The collimator lenses 11 to 17 are closely arranged in the array direction of the light emission points of the GaN-based semiconductor lasers LD1 to LD7 so that a length direction of the collimator lenses 11 to 17 is orthogonal to the array direction of the light emission points (the horizontal direction of FIG. 17).

On the other hand, the laser, which includes an active layer whose light emission width is 2 μm and emits the laser beams B1 to B7 while a spread angle in the direction parallel to the active layer is 10° and the spread angle in the direction orthogonal to the active layer is 30°, is used as the GaN-based semiconductor lasers LD1 to LD7. The GaN-based semiconductor lasers LD1 to LD7 are provided so that the light emission points are arranged in line in the direction parallel to the active layer.

The laser beams B1 to B7 emitted from each light emission point are incident while the direction in which the spread angle is larger corresponds to the length direction of the elongated-shaped collimator lenses 11 to 17 and the direction in which the spread angle is smaller corresponds to the width direction (the direction orthogonal to the length direction) of the elongated-shaped collimator lenses 11 to 17. That is to say, each width of the collimator lenses 11 to 17 is 1.1 mm, the length is 4.6 mm, the beam diameter in the horizontal direction of the laser beams B1 to B7 incident to the collimator lenses 11 to 17 is 0.9 mm, and the beam diameter in the vertical direction is 2.6 mm. In each of the collimator lenses 11 to 17, a focal distance f₁ is 3 mm, NA is 0.6, and a lens arrangement pitch is 1.25 mm.

The condenser lens 20 is formed in an area including the optical axis of an a spheric circular lens by the parallel planes so that the condenser lens is longer in the array direction of the collimator lenses 11 to 17, i.e. the horizontal direction and is shorter in the direction orthogonal to the horizontal direction. In the condenser lens 20, a focal distance f₂ is 23 mm and NA is 0.2. The condenser lens 20 is also formed by molding the resin or the optical glass.

In the fiber array light source 3000 having the above configuration, each of the laser beams B1 to B7 is emitted from each of the GaN-based semiconductor laser LD1 to LD7 constituting the multiplex laser light source while the laser beams B1 to B7 are a diverging ray, and the laser beams B1 to B7 is caused to be parallel to one another by the corresponding collimator lenses 11 to 17. The parallel laser beams B1 to B7 are condensed by the condenser lens 20 and focused on the incident end face of the core 30 a of the multi-mode optical fiber 30.

In the embodiment, the condenser optical system includes the collimator lenses 11 to 17 and the condenser lens 20, and the multiplex optical system includes the condenser optical system and the multi-mode optical fiber 30. That is to say, the laser beams B1 to B7 condensed by the condenser lens 20 are incident to the core 30a of the multi-mode optical fiber 30 to propagate through the optical fiber. Then, the laser beams B1 to B7 are multiplexed into one laser beam B to be outputted from the optical fiber 31 connected to the outgoing end portion of the multi-mode optical fiber 30.

In each laser module, in the case where coupling efficiency of the laser beams B1 to B7 to the multi-mode optical fiber 30 is 0.85 and the each output of the GaN-based semiconductor lasers LD1 to LD7 is 30 mW (in the case of the use of the single-mode laser), the multiplexed laser beam B having the output of 180 mW (=30 mW×0.85×7) can be obtained for each of the arrayed optical fibers 31. Accordingly, the output is about 18 W (=180 mW×100) at the laser-outgoing unit 68 where the 100 optical fibers 31 are arrayed.

In the laser-outgoing unit 68 of the fiber array light source 3000, the light emission points having high luminance are arrayed in line along the main scanning direction. In the conventional fiber light source in which the laser beam emitted from the single semiconductor laser is connected to one optical fiber, since the output is low, the desired output can be obtained when the many columns of the semiconductor lasers are arrayed. However, the multiplex laser light source used in the embodiment has the high output, so that only a few columns can obtain the desired output, e.g. one column of the semiconductor lasers.

For example, in the conventional fiber light source in which the semiconductor laser and the optical fiber are connected to each other one-to-one, the laser having the output of about 30 mW is usually used as the semiconductor laser, and the multi-mode optical fiber is used as the optical fiber. In the multi-mode optical fiber, the core diameter is 50 μm, the clad diameter is 125 μm, and NA (number of the opening) is 0.2. When the output of about 18 W is obtained, it is necessary to bundle the 864 (8×108) multi-mode optical fibers. Since a light emission area is 13.5 mm² (1 mm×13.5 mm), the luminance at the laser-outgoing unit 68 is 1.3 (MW/m²) and the luminance per one optical fiber is 8 (MW/M²).

On the contrary, in the embodiment, as described above, since the output of about 18 W can be obtained by the 100 multi-mode optical fibers and the light emission area at the laser-outgoing unit 68 is 0.3125 mm² (0.025 mm×12.5 mm), the luminance at the laser-outgoing unit 68 is 57.6 (MW/m²) and the luminance can be increased about 44 times compared with the conventional fiber/light source. Further, the luminance per one optical fiber is 288 (MW/m²) and the luminance can be increased about 36 times compared with the conventional fiber light source.

In the laser beam irradiating means shown in FIG. 28, instead of the fiber array light source 3000 formed so as to output the laser beams from the laser beam outgoing units arrayed in line or in the plurality of lines along the main scanning direction, it is also possible that the laser light source 300 is formed by a fiber bundle light source and the laser beam emitted from the fiber bundle light source is formed into the light beam having the desired beam intensity by utilizing the beam forming optical system 3002. The fiber bundle light source has the plurality of fiber light sources outputting the laser beam from the outgoing end face of the optical fiber after multiplexing the laser emitted from the plurality of GaN-based semiconductor lasers in the optical fiber, and each of the light emission points in the outgoing end faces of the plurality of optical fibers is arrayed in the bundled shape (the optical fibers are bundled in the fiber bundle light source, and the optical fibers can be bundle in various sectional shapes such as a round, a rectangle, and a polygon).

Further, the laser beam irradiating means shown in FIG. 28 is configured to use the fiber array light source 3000 as the laser light source 300 and to utilize the beam forming optical system 3002 which forms the laser beam emitted from the laser beam outgoing units arrayed in line along the main scanning direction orthogonal to the sub-scanning direction into the light beam having the desired beam intensity.

Therefore, in the laser beam irradiating means shown in FIG. 28, the same operations as the laser beam irradiating means including the spatial light modulator (DMD) 316 can be also obtained in such a manner that the fiber array light source 3000 is configured to be driven and controlled in each semiconductor laser. The same effects and advantages as the laser beam irradiating means shown in FIG. 2 are obtained.

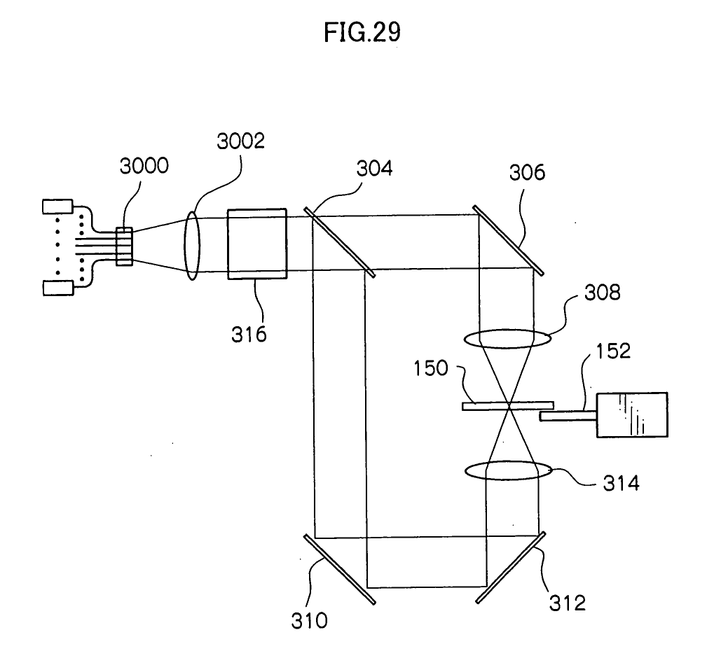

The configuration of the laser beam irradiating means in the laser annealing apparatus shown in FIG. 29 will be described below.

The laser beam irradiating means shown in FIG. 29 is configured to include the fiber array light source 3000 as the laser light source 300 and to include the beam forming optical system 3002 which forms the laser beam emitted from the laser beam outgoing unit arrayed in line along the main scanning direction orthogonal to the sub-scanning direction into the light beam having the desired beam intensity.

At the same time, the spatial light modulator (DMD) 316 is configured to be arranged between the beam forming optical system 3002 and the beam splitter 304 so as to modulate the light beam into the light beam having the desired beam intensity. Other constituent components are the same as the laser beam irradiating means shown in FIG. 2. In the laser beam irradiating means shown in FIG. 29, the same operations and advantages as the laser beam irradiating means shown in FIG. 22 are obtained except the action and advantage obtained by utilizing the fiber array light source 3000.

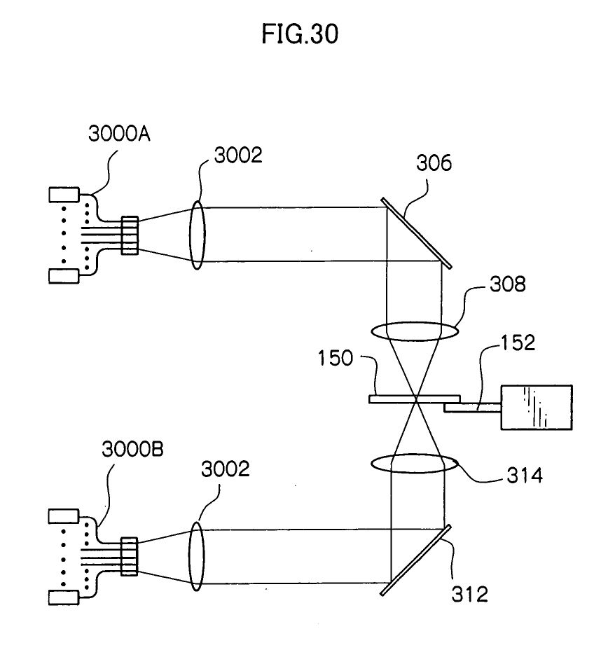

The configuration of the laser beam irradiating means in the laser annealing apparatus shown in FIG. 30 will be described below.

In the laser beam irradiating means shown in FIG. 30, the first optical path irradiating the a-Si layer which is of the subject with the laser beam from one of the surfaces (for example, from the surface) and the second optical path irradiating the a-Si layer with the laser beam from the other surface (for example, from the backside) are separately formed by utilizing two fiber array light sources 3000A and 3000B and the corresponding beam forming optical systems 3002 respectively.

Other constituent components in the laser beam irradiating means shown in FIG. 30 are the same as the laser beam irradiating means shown in FIG. 26. In the laser beam irradiating means shown in FIG. 30, the same operations and advantages as the laser beam irradiating means shown in FIG. 26 are obtained except the action and advantage obtained by utilizing the fiber array light source 3000.

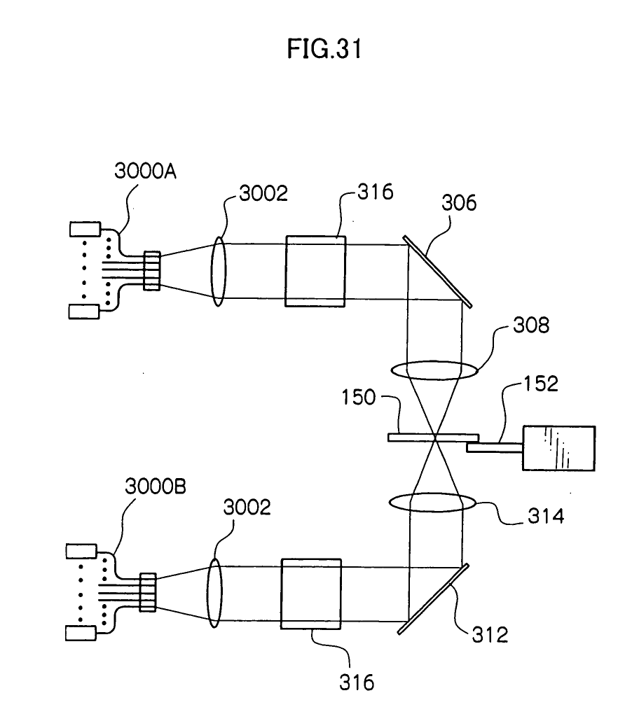

The configuration of the laser beam irradiating means in the laser annealing apparatus shown in FIG. 31 will be described below.

In the laser beam irradiating means shown in FIG. 31, the first optical path irradiating the a-Si layer which is of the subject with the laser beam from one of the surfaces (for example, from the surface) and the second optical path irradiating the a-Si layer with the laser beam from the other surface (for example, from the backside) are separately formed by utilizing two fiber array light sources 3000A and 3000B and the corresponding beam forming optical systems 3002 respectively.

At the same time, the spatial light modulator (DMD) 316 is arranged between the beam forming optical system 3002 and the mirror for beam irradiation 306 in the first optical path, and the spatial light modulator (DMD) 316 is also arranged between the beam forming optical system 3002 and the mirror for beam irradiation 312 in the second optical path.

Other constituent components in the laser beam irradiating means shown in FIG. 31 are the same as the laser beam irradiating means shown in FIG. 27. In the laser beam irradiating means shown in FIG. 31, the same operations and advantages as the laser beam irradiating means shown in FIG. 27 are obtained except the action and advantage obtained by utilizing the fiber array light source 3000.

[Operation of Laser Annealing Apparatus]

The operation of the laser annealing apparatus will be described below.

As shown in FIG. 1, in the laser annealing apparatus, the stage 152 in which the substrate 150 (or the substrate 150A) of the annealing is absorbed on the surface is moved at constant speed along the guides 158 from an upstream side of the gate 160 to a downstream side by the driving device (not shown). When the stage 152 passes through below the gate 160, the front end of the substrate 150 is sensed by the sensors 164 attached to the gate 160. Accordingly, the exposure start position is determined and the laser light source 300 (300A, 300B, 3000, 3000A, or 3000B) is driven and controlled to start the laser annealing process.

At this point, in the laser annealing apparatus including the spatial light modulator (DMD) 316, the control signal from the mirror driving control unit is sent to the spatial light modulator (DMD) 316 to perform the on and off control of each micromirror in the spatial light modulator (DMD) 316, and the laser beam emitted from the laser light beam 300 to the spatial light modulator (DMD) 316 is reflected when the micromirrors are in the on-state. As a result, the image is formed on the a-Si film of the substrate 150 to perform the laser annealing process. Thus, the laser beam outgoing from the laser light source 300 is turned on and off in each pixel, and the substrate 150 is irradiated and annealed in each of the pixel unit (irradiation area) having substantially the same number as the number of pixels of the spatial light modulator (DMD) 316.

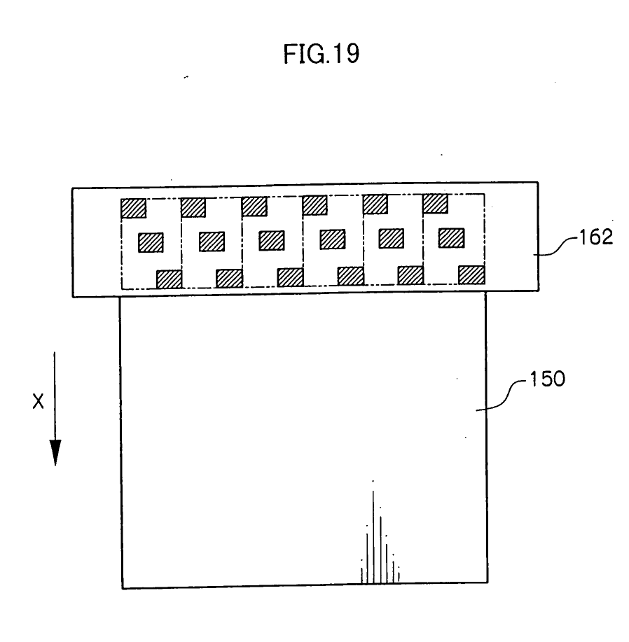

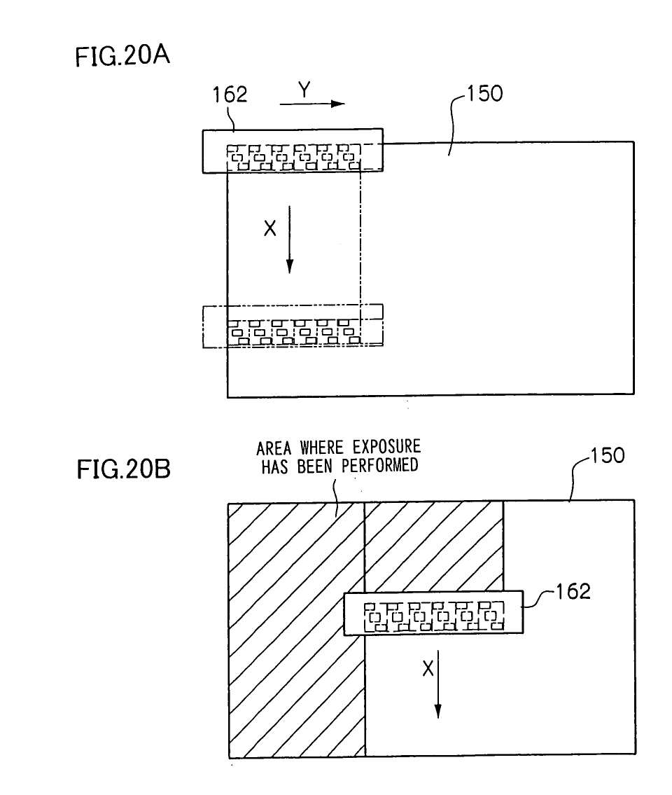

In the laser annealing apparatus, the sub-scan of the substrate 150 is performed in the direction opposite to the stage moving direction by moving the substrate 150 and the stage 152 at constant speed, and strip-shaped regions where the irradiation has been performed are formed by the scanner 162 as shown in FIG. 19 and FIGS. 20A and 20B.

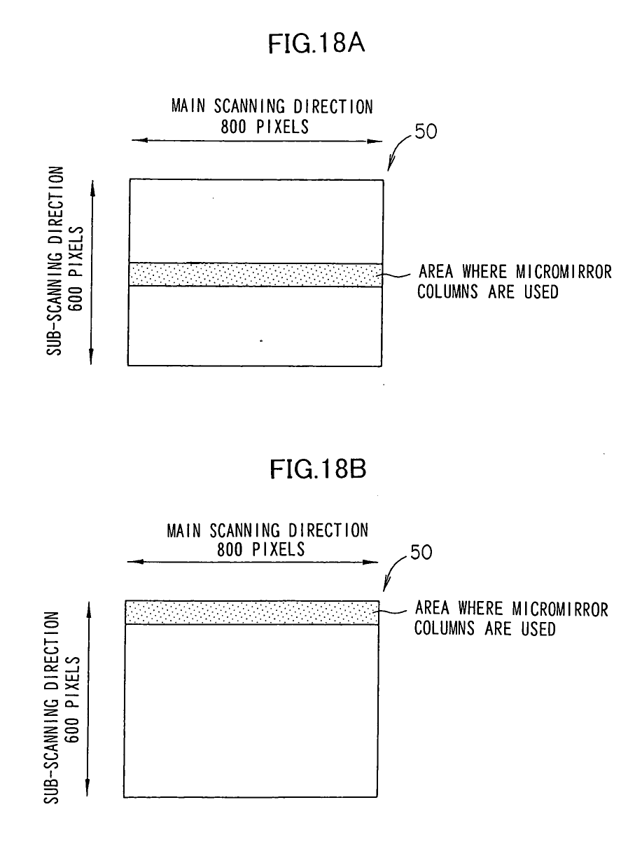

In the laser annealing apparatus including the spatial light modulator (DMD) 316, as shown in FIGS. 18A and 18B, for example, in the case where the spatial light modulator (DMD) 316 is configured so that the 600 sets of micromirror columns in which the 800 micromirrors are arrayed in the main scanning direction are arrayed in the sub-scanning direction, it is possible to control the spatial light modulator (DMD) 316 by the controller so that only a part of micromirror columns (for example, 800 pieces×10 columns) is driven.

As shown in FIG. 18A, it is also possible to use the micromirror columns arranged in the central portion of the spatial light modulator (DMD) 316. As shown in FIG. 18B, it is also possible to use the micromirror columns arranged in the end portion of the spatial light modulator (DMD) 316. In the case where defect is generated in a part of micromirrors, the micromirror columns can be properly changed according to the situation such that the micromirror columns in which the defect is not generated are used.

There is a limitation of data processing speed of the spatial light modulator (DMD) 316, and modulation speed per one line is determined in proportion to the number of pixels used, so that the modulation speed per one line is increased by using only a part of micromirror columns.

In the laser annealing apparatus, when the sub-scan of the substrate 150 performed by the scanner 162 is finished and the back end of the substrate 150 is sensed by the sensor 164, the stage 152 returns to an origin which is located on the most upstream side of the gate 160 along the guides 158 by the driving device (not shown), and the stage 152 is moved again at constant speed along the guides 158 from an upstream side of the gate 160 to a downstream side.

The laser annealing apparatus has the following advantages A1 to A5, because the high-quality semiconductor laser is used as the laser light source instead of the excimer laser, which is of the gas laser.

A1) The output of the light beam is stabilized, and the polysilicon film in which the diameters of the crystal grains are uniform can be reproducibly manufactured.

A2) Since the semiconductor laser is the fully solid-state laser, the semiconductor laser has high reliability in which the semiconductor laser can be driven for several tens thousands hours. In the semiconductor laser, it is difficult that breakage of the light beam outgoing end face occurs, and high peak power can be realized.

A3) Compared with the case in which the excimer laser, which is of a gas laser is used, miniaturization can be realized and the maintenance becomes very simple. Further, energy efficiency is as high as 10% to 20%.

A4) Since the semiconductor laser is the laser in which CW (continuous) drive can be basically performed, even if pulse drive of the semiconductor laser is performed, the amount of absorption of amorphous silicon, repeated frequency according to a heat value, and a pulse width (duty) can be freely set. For example, an arbitrary repeated operation ranging from several Hz to several MHz can be realized and an arbitrary pulse width ranging from several psec to several hundreds msec can be realized. Particularly, the repeated frequency can be set up to the range of several tens MHz. Similarly to the CW drive, the continuous grain boundary can be formed. Further, since the repeated frequency can become large, the high-speed annealing can be performed.

A5) Since the CW drive of the semiconductor laser can be performed to scan the annealing surface in a predetermined direction with the continuous laser beam, orientation of the crystal growth can be controlled and the continuous grain boundary can be formed, and the polysilicon film having the high carrier mobility can be formed.

The laser annealing apparatus has the following advantages B1 to B3, when the fiber array light source 3000 in which the outgoing end faces of the optical fibers of the multiplex laser light source are arrayed is used as the laser light source in the laser annealing apparatus.

B1) Usually in the laser annealing apparatus, high light-density ranging from 400 mJ/cm² to 700 mJ/cm² is required in the annealing surface (exposure surface). However, in the embodiment, the high output and high light density in the multi-beam can be easily achieved by increasing the number of fibers arrayed and the number of laser beams multiplexed. For example, when the fiber output of one multiplex laser light source is set to 180 mW, the high output of 100 W can be stably obtained by bundling the 556 multiplex laser light sources. Additionally, the quality of the laser beam is stabilized and high power density. Accordingly, the laser annealing apparatus of the invention can correspond to the increase in deposition area of the low-temperature polysilicon in the future and high throughput.

B2) The outgoing end unit of the optical fiber can be attached exchangeably by using the connector or the like, and the maintenance becomes easy.

B3) Since the multiplex module in which the small semiconductor lasers are multiplexed is small, the light source unit can be miniaturized, compared with the excimer laser.

In the case where the clad diameter of the outgoing end of the optical fiber is formed so as to be smaller than the clad diameter of the incident end, the diameter of light emission unit is further decreased, and the high luminance of the fiber array light source 3000 can be achieved. Therefore, the laser annealing apparatus having the deeper focal depth can be realized. For example, even if the annealing is performed in super-fine resolution when the beam diameter is not more than 1 μm and the resolution is not more than 0.1 μm, the deep focal depth can be obtained, and high-speed and fine annealing can be performed.

It is also possible that the laser light source in the above laser annealing apparatus is formed by a gas laser pumped solid-state laser in which a Pr_{3 +} doped solid-state laser crystal is excited by the gas laser such as an Ar laser, the solid-state laser in which the Pr_{3 +} doped solid-state laser crystal is excited by the SH light beam (Second Harmonic) of a lamp pumped solid-state laser, or the solid-state laser in which the Pr_{3 +} doped solid-state laser crystal is excited by the SHG (Second Harmonic Generation) generating the laser beam having the wavelength of a blue light range.

It is also possible that the laser light source in the above laser annealing apparatus is formed by a laser diode pumped solid-state laser in which the Pr_{3 +} doped solid-state laser crystal is excited by an InGaN-based laser diode (laser diode whose active layer includes an InGaN-based material), an InGaNAs based laser diode (laser diode whose active layer includes an InGaNAs based material), or a GaNAs based laser diode (laser diode whose active layer includes a GaNAs based material).

Further, the laser light source in the above laser annealing apparatus can be formed by the laser diode pumped solid-state laser in which the solid-state laser crystal is excited by the GaN-based laser diode, the laser diode having the active layer including InGaN, InGaNAs, or GaNAs. Both Pr_{3 +} and at least one of Er_{3 +}, Ho_{3 +}, Dy_{3 +}, Eu_{3 +}, Sm_{3 +}, Pm_{3 +}, and Nd_{3 +}are doped in the solid-state laser. Consequently, it is possible to oscillate the laser beam of a blue light range whose wavelength ranges from 465 to 495 nm, the laser beam of a green light range whose wavelength ranges from 515 to 555 nm, and the laser beam of a red light range whose wavelength ranges from 600 to 660 nm.

It is possible that the solid laser crystal such as Nd_{3 +} doped YAG(Y₃Al₅O₂), liYF₄, and YVO₄ is formed by the SHG (Second Harmonic Generation) solid-state laser which generates the SH light beam (Second Harmonic) of a semiconductor laser excited Nd solid-state laser excited by the laser diode.

It is also possible that the laser beam having the wavelength of 488 nm or the laser beam having the wavelength of 514.5 nm in the Ar laser is used as the laser light source in the laser annealing apparatus. Further, it is also possible to use a multi-line Ar laser.

What is claimed is:

1. A laser annealing apparatus comprising:
a laser light source, which includes a GaN-based semiconductor laser;
a first optical path which irradiates a film-shaped subject to be annealed from a first surface of the subject to be annealed with a first laser beam divided from a laser beam emitted from the laser light source;
a second optical path which irradiates an irradiation position of the film-shaped subject to be annealed from the other surface of the film-shaped subject to be annealed with a second laser beam divided from the laser beam emitted from the laser light source, the irradiation position corresponding to a position on the first surface being irradiated by the first laser beam; and
a scanning unit, which performs scanning by relatively moving the film-shaped subject to be annealed and the first and second laser beams.

2. A laser annealing apparatus comprising:
a first laser light source and a second light source which emit a first laser beam and a second laser beam respectively, at least one of the first laser light source and the second light source including a GaN-based semiconductor laser;
a first optical path which irradiates a film-shaped subject to be annealed from a first surface of the film-shaped subject to be annealed with the first laser beam emitted from the first laser light source;
a second optical path which irradiates an irradiation position on the other surface of the film-shaped subject to be annealed with the second laser beam emitted from the second laser light source, the irradiation position corresponding to a position on the first surface being irradiated by the first laser beam; and
a scanning unit, which performs scanning by relatively moving the film-shaped subject to be annealed and the first and second laser beams.

3. A laser annealing apparatus according to claim 2, wherein the first laser beam emitted from the first laser light source has a first wavelength, the second laser beam emitted from the second laser light source has a second wavelength, and the first wavelength of the first laser beam and the second wavelength of the second laser beam are set so that a total absorption energy distribution in the film becomes uniform in a film thickness direction of the subject to be annealed, the total absorption energy distribution being equal to a sum of a first absorption energy distribution in the film in the case where the film-shaped subject to be annealed is irradiated with the first laser beam having the first wavelength emitted from the first laser light source from the first surface of the subject to be annealed and a second absorption energy distribution in the film in the case where the film-shaped subject to be annealed is irradiated with the second laser beam having the second wavelength emitted from the second laser light source from the other surface of the subject to be annealed.

4. A laser annealing apparatus according to claim 1, wherein the laser light source emits a laser beam having a wavelength satisfying the following condition,
α(λ)d<4.6
where α(λ) is an absorption coefficient when the laser beam is absorbed in the film-shaped subject to be annealed, and d is a film thickness of the film-shaped subject to be annealed.

5. A laser annealing apparatus comprising:
a laser light source, which emits a laser beam;
a first optical path which irradiates a film-shaped subject to be annealed with the laser beam on one surface of the film-shaped subject to be annealed;
a second optical path which irradiates the subject to be annealed with the laser beam on another surface of the film-shaped subject to be annealed; and
a scanning unit for performing scanning by relatively moving the film-shaped subject to be annealed and the laser beam,
wherein a light energy distribution in the laser beam emitted from the laser light source is a distribution having a gradient in which light energy intensity is strong on a front end side in a scanning direction of the subject to be annealed and is gradually decreased toward a back end side in the scanning direction.

6. A laser annealing apparatus according to claim 1, wherein the laser light source is configured as a fiber array light source.

7. A laser annealing apparatus according to claim 2, wherein the first and second laser light sources are configured as fiber array light sources.

8. A laser annealing apparatus according to claim 4, wherein the laser light source is configured as a fiber array light source.

9. A laser annealing apparatus according to claim 5, wherein the laser light source is configured as a fiber array light source.

10. A laser annealing apparatus according to claim 6, wherein a clad diameter of a plurality of optical fibers constituting the fiber array light source is not more than 80 μm.

11. A laser annealing apparatus according to claim 6, wherein a clad diameter of a plurality of optical fibers constituting the fiber array light source is not more than 60 μm.

12. A laser annealing apparatus according to claim 6, wherein a clad diameter of a plurality of optical fibers constituting the fiber array light source is not more than 40 μm.

13. A laser annealing apparatus according to claim 6, wherein a clad diameter of a plurality of optical fibers constituting the fiber array light source is not less than 10 μm.

14. A laser annealing method comprising:
dividing a laser beam emitted from a laser light source, which includes a GaN-based semiconductor laser, into two laser beams;
irradiating a film-shaped subject to be annealed from a first surface of the subject to be annealed with a first laser beam, which is one of the divided laser beams;
irradiating an irradiation position of the film-shaped subject to be annealed from the other surface of the film-shaped subject to be annealed with a second laser beam, which is the other of the divided laser beams, the irradiation position corresponding to a position on the first surface being irradiated by the first laser beam; and
scanning by relatively moving the film-shaped subject to be annealed and the first and second laser beams.

15. A laser annealing method comprising:
irradiating a film-shaped subject to be annealed from a first surface of the film-shaped subject to be annealed with a first laser beam emitted from a first laser light source including a GaN-based semiconductor laser;
irradiating an irradiation position on the other surface of the film-shaped subject to be annealed with a second laser beam emitted from a second laser light source, the irradiation position corresponding to a position on the first surface being irradiated by the first laser beam; and
scanning by relatively moving the film-shaped subject to be annealed and the first and second laser beams.

16. A laser annealing method comprising:
irradiating a film-shaped subject to be annealed with a laser beam emitted from a laser light source on one surface of the film-shaped subject to be annealed;
irradiating the subject to be annealed with the laser beam on another surface of the film-shaped subject to be annealed; and
scanning by relatively moving the film-shaped subject to be annealed and the laser beam,
wherein a light energy distribution in the laser beam emitted from the laser light source is set to be a distribution having a gradient in which light energy intensity is strong on a front end side in a scanning direction of the subject to be annealed and is gradually decreased toward a back end side in the scanning direction.
